(19) United States
(12) Patent Application Publication
(10) Pub. No.: US 2026/0027821 A1
(43) Pub. Date: Jan. 29, 2026

(54) INK JET PRINTING METHOD, INK JET PRINTING APPARATUS, AND AN ELECTRONIC APPARATUS FORMED UTILIZING THE SAME

(71) Applicant: Samsung Display Co., Ltd., Yongin-si (KR)

(72) Inventors: Katsuyuki Hirato, Yongin-si (KR); Wooree Ko, Yongin-si (KR); Euna Ko, Yongin-si (KR); Eunbyuel Lee, Yongin-si (KR)

(21) Appl. No.: 19/251,589

(22) Filed: Jun. 26, 2025

(30) Foreign Application Priority Data
Jul. 25, 2024 (KR) 10-2024-0098962

(51) Int. Cl. B41J 2/045; B41J 3/28; B41J 3/407; G01N 15/075; G06K 15/02; G06K 15/10

(52) U.S. Cl. CPC B41J 2/04561; B41J 2/0456; B41J 2/04581; B41J 3/28; B41J 3/407; G01N 15/075; G06K 15/102; G06K 15/186

(57) ABSTRACT

An inkjet printing method, an inkjet printing apparatus, and an electronic apparatus formed utilizing the same are provided. The inkjet printing method includes generating volume data by measuring a volume of an ink droplet discharged from each of a plurality of nozzles, generating particle number data by measuring a number of solute particles within the ink droplet discharged from each of the plurality of nozzles, forming a first nozzle group by grouping, based on the volume data and the particle number data, nozzles that are to discharge ink into a first region from among the plurality of nozzles, and discharging the ink into the first region by the nozzles of the first nozzle group.

### CROSS-REFERENCE TO RELATED APPLICATION

The present application claims priority to and the benefit of Korean Patent Application No. 10-2024-0098962, filed on Jul. 25, 2024, in the Korean Intellectual Property Office, the entire content of which is hereby incorporated by reference.

### BACKGROUND

### 1. Field

One or more embodiments relate to a method and an apparatus, and, for example, to an ink jet printing method, an ink jet printing apparatus, and an electronic apparatus formed utilizing the same.

### 2. Description of the Related Art

Mobility-based electronic devices have become widely used. In addition to small electronic devices such as mobile phones, tablet personal computers (PCs) have recently been widely used as mobile electronic devices.

Such mobile electronic devices include display apparatuses to provide various functions, for example, visual information, such as images and/or videos, to users. Recently, the proportion of display apparatuses in electronic devices is increasing, and structures that may be bent to a set or certain angle from a flat state have also been developed.

Display apparatuses may include various layers formed via various processes. For example, display apparatuses may include a functional layer that performs an optical function and a color filter layer for improving color purity, and these layers may be formed via a process, for example, an inkjet printing process, of discharging ink onto a display substrate. For the inkjet printing process, an apparatus for manufacturing a display apparatus may include a spray unit for discharging ink.

The above-described background technology is information that the inventor possessed for the derivation of the disclosure or acquired in the process of deriving the disclosure, and it cannot be said that it is known technology disclosed to the general public before the filing of the disclosure.

### SUMMARY

In embodiments of a display apparatus employing an inkjet printing process, uniform (e.g., substantially uniform) quality during droplet application may be utilized or required during inkjet printing to prevent mura.

One or more embodiments include an inkjet printing method and an inkjet printing apparatus, which are capable of providing uniform (e.g., substantially uniform) quality of droplet application during inkjet printing.

However, the foregoing is an example, and the objectives of embodiments of the present disclosure to solve are not limited thereby.

Additional aspects of embodiments will be set forth in part in the description which follows and, in part, will be apparent from the description, or may be learned by practice of the presented embodiments of the disclosure.

According to one or more embodiments, an inkjet printing method includes generating volume data by measuring a volume of an ink droplet discharged from each of a plurality of nozzles, generating particle number data by measuring a number of solute particles within the ink droplet discharged from each of the plurality of nozzles, forming a first nozzle group by grouping, based on the volume data and the particle number data, nozzles that are to discharge ink into a first region from among the plurality of nozzles, and discharging the ink into the first region by the nozzles of the first nozzle group.

In an embodiment, the forming of the first nozzle group may include selecting some of the plurality of nozzles such that a number of solute particles within ink droplets discharged into the first region is close to a target number of particles.

In an embodiment, a sum of numbers of solute particles in respective ink droplets discharged by the nozzles of the first nozzle group may be the same as the target number of particles.

In an embodiment, the forming of the first nozzle group may further include selecting some of the plurality of nozzles such that a volume of the ink droplets discharged into the first region is close to a target volume.

In an embodiment, a sum of volumes of respective ink droplets discharged by the nozzles of the first nozzle group may be the same as the target volume.

In an embodiment, the forming of the first nozzle group may further include selecting a combination of nozzles adjacent to the first region, from among combinations of nozzles, which satisfy the target number of particles and the target volume.

In an embodiment, the inkjet printing method may further include forming a second nozzle group by grouping, based on the volume data and the particle number data, nozzles that are to discharge ink to a second region from among the plurality of nozzles.

In an embodiment, the forming of the second nozzle group may include selecting some of the plurality of nozzles such that a number of solute particles within ink droplets discharged into the second region is close to a target number of particles.

In an embodiment, the forming of the second nozzle group may further include selecting some of the plurality of nozzles such that a volume of the ink droplets discharged into the second region is close to a target volume.

In an embodiment, the generating of the particle number data may include measuring a number of particles within each of the ink droplets discharged from the nozzles by using laser induced breakdown spectroscopy.

In an embodiment, the generating of the volume data and the generating of the particle number data may include information about a volume of a droplet according to a discharge waveform of each of the plurality of nozzles and information about a number of solute particles within the droplet.

In an embodiment, the generating of the volume data may include slightly adjusting the volume of the discharged ink droplet by slightly adjusting a voltage applied to each of the plurality of nozzles.

According to one or more embodiments, an inkjet printing apparatus includes a stage on which a display substrate is seated, a spray unit that faces the stage and is configured to discharge ink onto the display substrate, and a controller configured to control the spray unit, wherein the spray unit includes a head unit including a plurality of nozzles, a volume measuring unit that is adjacent to the head unit and is configured to measure volumes of ink droplets discharged by the nozzles, and a particle number measuring unit that is adjacent to the head unit and is configured to measure a number of solute particles within the ink droplets discharged by the nozzles.

In an embodiment, the particle number measuring unit may be configured to measure a number of particles within each of the ink droplets discharged from the nozzles by using laser induced breakdown spectroscopy.

In an embodiment, the volume measuring unit may include at least one selected from among a line scan camera and a chromatic confocal sensor.

In an embodiment, the controller may be configured to generate volume data by measuring a volume of an ink droplet discharged from each of the plurality of nozzles.

In an embodiment, the controller may be further configured to select, based on the volume data, some of the plurality of nozzles such that a volume of ink droplets discharged into a first region is close to a target volume.

In an embodiment, the controller may be further configured to generate particle number data by measuring a number of solute particles within an ink droplet discharged from each of the plurality of nozzles.

In an embodiment, the controller may be further configured to select, based on the particle number data, some of the plurality of nozzles such that a number of solute particles within ink droplets discharged into a first region is close to a target number of particles.

According to one or more embodiments, an electronic apparatus includes a layer formed by an inkjet printing method including generating volume data by measuring a volume of an ink droplet discharged from each of a plurality of nozzles, generating particle number data by measuring a number of solute particles within the ink droplet discharged from each of the plurality of nozzles, forming a first nozzle group by grouping, based on the volume data and the particle number data, nozzles that are to discharge ink into a first region from among the plurality of nozzles, and discharging the ink into the first region by the nozzles of the first nozzle group.

Aspects and features of embodiments other than those described above will become apparent from the following drawings, claims, and detailed descriptions to embody the disclosure below.

### BRIEF DESCRIPTION OF THE DRAWINGS

The above and other aspects and features of certain embodiments of the disclosure will be more apparent from the following description taken in conjunction with the accompanying drawings, in which:

FIG. 1 is a perspective view schematically showing an apparatus for manufacturing a display apparatus according to an embodiment;

FIG. 2 is a plan view schematically showing a spray unit according to an embodiment;

FIGS. 3-7 are diagrams schematically showing a method of manufacturing a display apparatus according to an embodiment;

FIGS. 8-9 are diagrams schematically showing a method of manufacturing a display apparatus according to an embodiment;

FIGS. 10-11 are diagrams schematically showing a method of manufacturing a display apparatus according to an embodiment;

FIG. 12 is a perspective view schematically showing a display apparatus according to an embodiment;

FIG. 13 is a cross-sectional view schematically showing the display apparatus according to an embodiment;

FIG. 14 shows each of optical layers of a functional layer of FIG. 13;

FIG. 15 is an equivalent circuit diagram showing a light-emitting diode included in a display apparatus according to an embodiment and a sub-pixel circuit electrically connected to the light-emitting diode; and

FIG. 16 is a cross-sectional view schematically showing the display apparatus according to an embodiment.

### DETAILED DESCRIPTION

Reference will now be made in more detail to embodiments, examples of which are illustrated in the accompanying drawings, wherein like reference numerals refer to like elements throughout the present specification. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

Various suitable modifications may be applied to the present embodiments, and example embodiments will be illustrated in the drawings and described in the detailed description section. The effect and features of embodiments of the disclosure, and a method to achieve the same, will be clearer referring to the detailed descriptions below with the drawings. However, the present embodiments may be implemented in various suitable forms, and are not limited to the embodiments presented below.

Hereinafter, embodiments of the present disclosure will be described in more detail with reference to the accompanying drawings, and in the description with reference to the drawings, the same or corresponding components are indicated by the same reference numerals and redundant descriptions thereof are omitted.

In the following embodiment, it will be understood that although the terms “first,” “second,” and/or the like. may be used herein to describe various components, these components should not be limited by these terms. These terms are only used to distinguish one component from another.

In the following embodiment, the expression of singularity in the present specification includes the expression of plurality unless clearly specified otherwise in context.

In the following embodiment, it will be further understood that the terms “comprises” and/or “comprising” used herein specify the presence of stated features or components, but do not preclude the presence or addition of one or more other features or components.

In the following embodiment, it will be understood that if (e.g., when) a layer, region, or component is referred to as being “on” or “formed on” another layer, region, or component, it can be directly or indirectly on or formed on the other layer, region, or component. For example, intervening layers, regions, or components may be present.

Sizes of components in the drawings may be exaggerated for convenience of explanation. In embodiments, because sizes and thicknesses of components in the drawings may be arbitrarily illustrated for convenience of explanation, the following embodiments are not limited thereto.

In the following embodiment, the x-axis, the y-axis, and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

If (e.g., when) a certain embodiment may be implemented differently, a specific process order may be performed differently from the described order. For example, two consecutively described processes may be performed substantially at the same time or performed in an order opposite to the described order.

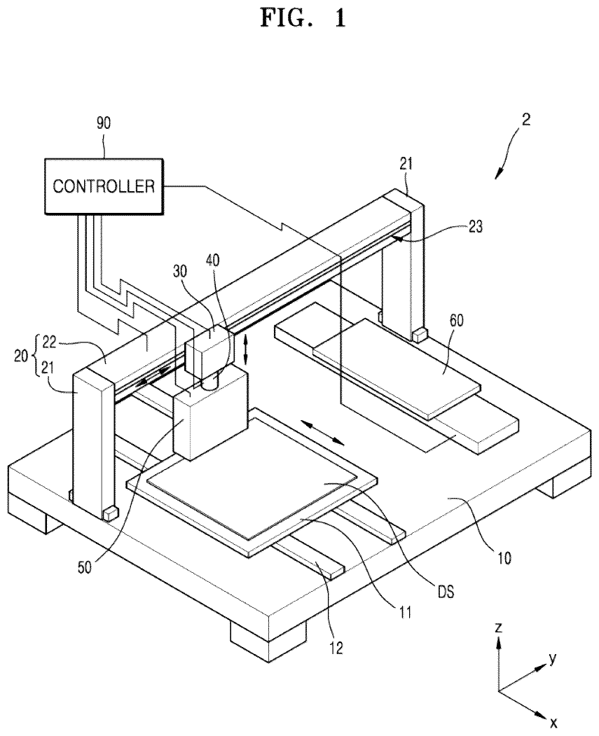

FIG. 1 is a perspective view schematically showing an apparatus 2 for manufacturing a display apparatus according to an embodiment. In an embodiment, the apparatus 2 for manufacturing a display apparatus includes an inkjet printing apparatus for discharging ink on a display substrate DS, but the disclosure is not necessarily limited thereto.

Referring to FIG. 1, the apparatus 2 for manufacturing a display apparatus may include a support 10, a gantry 20, a first moving unit 30, a second moving unit 40, a spray unit 50, a maintenance unit 60, and a controller 90.

The support 10 is a component on which other components are seated or provided, and in an embodiment, the support 10 may have a plane defined by a first direction (for example, an x direction of FIG. 1) and a second direction (for example, a y direction of FIG. 1) crossing the first direction. In embodiments, the support 10 may have a quadrangular plane as shown in FIG. 1, but the disclosure is not limited thereto, and the support 10 may have various suitable shapes, such as polygon or circle (e.g., a generally circular shape).

A stage 11 may be further provided on the support 10. The stage 11 is on the support 10 and may have a plane defined by the first direction and the second direction. The display substrate DS may be seated or provided on the stage 11, and the stage 11 may include an alignment mark to align the display substrate DS. In this regard, the display substrate DS is a portion of a display apparatus being manufactured and may be an object on which the display substrate DS discharges ink. In embodiments, the discharged ink may adhere to the display substrate DS and form a partial layer of the display apparatus. The stage 11 may form a work region for an inkjet printing process.

Guide units 12 may be further provided between the support 10 and the stage 11. The guide units 12 are on the support 10 and may be spaced apart from each other under the stage 11. For example, the number of the guide units 12 is two, and the guide units 12 may be spaced apart from each other in the second direction so as to be adjacent to both sides of the stage 11. Each of the guide units 12 may extend in the first direction, and the extension length of each of the guide units 12 in the first direction may be greater than the length of the stage 11 in the first direction.

The guide units 12 may guide the stage 11 to enable linear motion along the extension direction of the guide units 12. The guide units 12 may include, for example, a linear motion rail.

In an embodiment, the stage 11 may linearly reciprocate along the guide units 12. The stage 11 may perform linear motion manually, or may perform linear motion automatically by including a motor cylinder, and/or the like. For example, the stage 11 may perform linear motion automatically by including a linear motion block that moves along the linear motion rail.

The gantry 20 may be on the support 10 and may include vertical members 21 and a horizontal member 22. FIG. 1 shows that the vertical members 21 and the horizontal member 22 each have a rectangular bar shape, but the shapes of the vertical members 21 and the horizontal member 22 are not limited thereto.

The vertical members 21 of the gantry 20 may extend in a third direction (for example, a z direction of FIG. 1) crossing each of the first direction and the second direction. The number of the vertical members 21 may be, for example, two, and the vertical members 21 may be provided at both sides of the stage 11, with the stage 11 therebetween.

The horizontal member 22 of the gantry 20 may extend in the second direction between the vertical members 21. Both ends of the horizontal member 22 may be respectively connected to upper portions of the vertical members 21. The horizontal member 22 may include a first groove 23 extending along the extension direction of the horizontal member 22, for example, in the second direction. The first groove 23 may be provided in one side surface of the horizontal member 22. For example, the first groove 23 may be provided in a surface of the horizontal member 22, the surface facing the first direction. The first groove 23 may guide the first moving unit 30 to enable linear reciprocation along the extension direction of the first groove 23.

Hereinbefore, it has been described that the gantry 20 is fixed on the support 10, and the stage 11 moves in the first direction across the horizontal member 22 of the gantry 20, but the disclosure is not limited thereto. In embodiments, the stage 11 is fixed on the support 10, and the gantry 20 may move in the first direction on the support 10. In embodiments, both the stage 11 and the gantry 20 may move in the first direction. In embodiments, the gantry 20 and the stage 11 may move relative to each other in the first direction. Hereinafter, for convenience of explanation, because the gantry 20 and the stage 11 move relative to each other in the first direction, the description will be made assuming that the gantry 20 moves in the first direction.

The first moving unit 30 may linearly move in the second direction. The first moving unit 30 may be movably connected to one side surface of the horizontal member 22 of the gantry 20. For example, the first moving unit 30 may be on a surface of the horizontal member 22, in which the first groove 23 is provided. The first moving unit 30 may linearly reciprocate in the second direction along the first groove 23. In an embodiment, the first moving unit 30 may include a linear motor.

In an embodiment, the second moving unit 40 is on one side surface of the first moving unit 30 and may linearly reciprocate in the third direction. For example, the second moving unit 40 may be on a lower surface of the first moving unit 30. In embodiments, the lower surface of the first moving unit 30 may be a surface of the first moving unit 30, which faces the stage 11. In an embodiment, the second moving unit 40 may include a pneumatic cylinder. In embodiments, the second moving unit 40 may rotate and move around an axis extending in the third direction. To this end, the second moving unit 40 may include, for example, an electric motor, a pneumatic motor, and/or the like.

In an embodiment, the spray unit 50 may be on a lower surface of the second moving unit 40. The spray unit 50 may move together with the first moving unit 30 and the second moving unit 40. In embodiments, the first moving unit 30 may transfer the spray unit 50 in the second direction, and the second moving unit 40 may transfer the spray unit 50 in the third direction. For example, the movement range of the spray unit 50 may be substantially the same as a region occupied by the support 10. The spray unit 50 may also be rotated by the second moving unit 40 around an axis extending in the third direction

The spray unit 50 may discharge ink droplets toward the display substrate DS. In embodiments, the ink may be a material applied to form a color filter layer on the display substrate DS. In embodiments, the ink may be a polymer and/or low-molecular-weight organic material corresponding to an emission layer of an organic light-emitting display apparatus. In embodiments, the ink may be a red, green, or blue liquid mixed with a liquid crystal, an alignment agent, and/or a solvent. In an embodiment, the ink may include a solution including inorganic particles such as quantum dot materials.

The maintenance unit 60 is on the support 10 and may be spaced apart from the stage 11 in the second direction. The maintenance unit 60 may be between the two vertical members 21 of the gantry 20. The maintenance unit 60 may be a stage for maintenance of the spray unit 50. In an embodiment, the maintenance unit 60 may include an ink removal unit to remove ink remaining in the spray unit 50. Accordingly, it is possible to prevent or reduce occurrence of ink discharge defects due to ink remaining in the spray unit 50. The spray unit 50 may move in the second direction via the horizontal member 22 of the gantry 20 and may be moved to the maintenance unit 60.

The controller 90 may be electrically connected to the stage 11, the guide units 12, the first moving unit 30, the second moving unit 40, and the spray unit 50. The controller 90 may control the position and operation of each component. In embodiments, the controller 90 is electrically connected to the maintenance unit 60 and may control the operation of the maintenance unit 60.

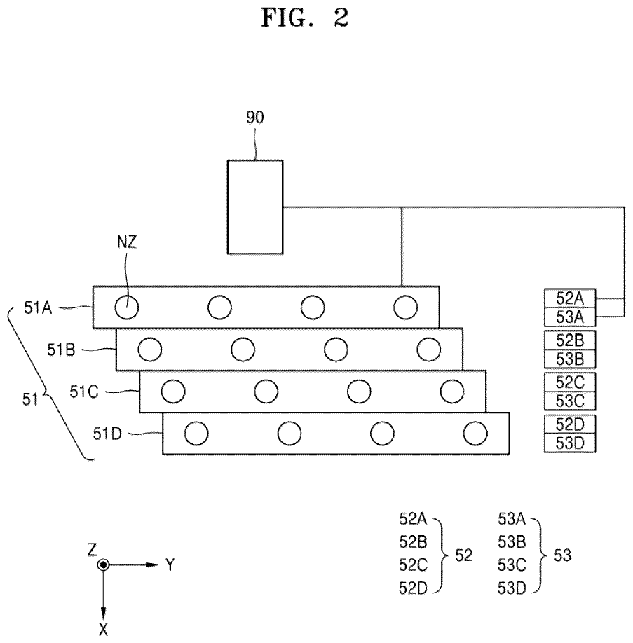

FIG. 2 is a plan view schematically showing a spray unit according to an embodiment.

Referring to FIG. 2, the spray unit 50 may include a head unit 51, a particle number measuring unit 52, and a volume measuring unit 53.

The head unit 51 may receive and discharge ink. In more detail, the head unit 51 may include a plurality of nozzles NZ. For example, the head unit 51 may extend in the second direction (y direction), and the plurality of nozzles NZ may be provided side by side along the extension direction of the head unit 51.

In an embodiment, the head unit 51 may be provided as a plurality, and a plurality of head units 51 may be provided side by side in the first direction (x direction). In the drawings, it is shown that the number of head units 51 is four, and in embodiments, the head unit 51 may include a first head unit 51A to a fourth head unit 51D. The foregoing is for convenience of explanation, and the disclosure is not limited thereto.

In embodiments, the head unit 51 may include a piezoelectric element. The head unit 51 may be configured to jet ink by using a piezoelectric effect. The piezoelectric element is provided in an internal space of the head unit 51, the piezoelectric element is connected to a switching module, and the switching module may be connected to a rod extending in the third direction (z direction). In embodiments, an elastic member, for example, a spring, may be provided on the rod to surround the rod. Considering the operation of the head unit 51, a power source is connected to the piezoelectric element, and thus, power may be supplied. Accordingly, the piezoelectric element may repeatedly contract and expand due to the piezoelectric effect, and accordingly, the switching module and the rod connected to the switching module may be vertically raised or lowered. The rod may discharge ink by pushing an ink solution out of the nozzles NZ by the vertical motion of rising or falling. This is an example, and a jetting method of the head unit 51 is not limited thereto.

The particle number measuring unit 52 may measure the number of solute particles within ink droplets discharged from the head unit 51, for example, from the nozzles NZ. In an embodiment, ink may include a solvent as a base and a solute within the solvent. For example, ink may include a solvent and functional particles within the solvent. The particle number measuring unit 52 may measure the number of solute particles from ink droplets discharged from the nozzles NZ. In an embodiment, the particle number measuring unit 52 may measure the number of solute particles within droplets by using laser induced breakdown spectroscopy (LIBS).

The particle number measuring unit 52 may be adjacent to the head unit 51. The particle number measuring unit 52 may be arranged adjacent to the head unit 51, and may measure the number of solute particles within each of droplets while moving over the droplets discharged by the nozzles NZ. For example, if (e.g., when) the number of head units 51 is four as shown in the drawings, the number of particle number measuring units 52 may be four corresponding to the number of head units 51. In embodiments, the particle number measuring unit 52 may include a first particle number measuring unit 52A to a fourth particle number measuring unit 52D. The first particle number measuring unit 52A may measure the number of solute particles within ink droplets discharged by nozzles NZ of the first head unit 51A, and for example, may measure the number of solute particles within ink droplets while moving in the second direction. In embodiments, it may be understood that the second particle number measuring unit 52B to the fourth particle number measuring unit 52D may measure the number of solute particles within ink droplets discharged by nozzles NZ of the second head units 51B to the fourth head unit 51D. In embodiments, the particle number measuring unit 52 and the head unit 51 may be integrally formed as a single body.

The volume measuring unit 53 may measure the volumes of ink droplets discharged from the head unit 51, for example, from the nozzles NZ. In an embodiment, the volume measuring unit 53 may include at least one selected from among a line scan camera and a chromatic confocal sensor.

The volume measuring unit 53 may be adjacent to the head unit 51. The volume measuring unit 53 may be adjacent to the head unit 51, and may measure the volume of each of droplets while moving over the droplets discharged by the nozzles NZ. In embodiments, the volume measuring unit 53 may be arranged adjacent to the head unit 51, and may measure the volumes of droplets by measuring the diameters of the droplets if (e.g., when) the nozzles NZ discharge the droplets. For example, if (e.g., when) the number of head units 51 is four as shown in the drawings, the number of volume measuring units 53 may be four corresponding to the number of head units 51. In embodiments, the volume measuring unit 53 may include a first volume measuring unit 53A to a fourth volume measuring unit 53D. The first volume measuring unit 53A may measure the volumes of ink droplets discharged by the nozzles NZ of the first head unit 51A, and for example, may measure the volumes of ink droplets while moving in the second direction. In embodiments, it may be understood that the second volume measuring unit 53B to the fourth volume measuring unit 53D may measure the volumes of ink droplets discharged by the nozzles NZ of the second head units 51B to the fourth head unit 51D. In embodiments, the volume measuring unit 53 is provided as a single unit, and thus, the single volume measuring unit 53 may measure all volumes of ink droplets discharged by the first head unit 51A to the fourth head unit 51D. In embodiments, the volume measuring unit 53 and the head unit 51 may be integrally formed as a single body.

In embodiments, the head unit 51, the particle number measuring unit 52, and the volume measuring unit 53 may be connected to the controller 90. The controller 90 may control movement of the head unit 51, control ink discharge from the nozzles NZ of the head unit 51, and/or control driving of the particle number measuring unit 52 and the volume measuring unit 53. In embodiments, as further described herein, the controller 90 may generate data from information obtained from the particle number measuring unit 52 and the volume measuring unit 53, and may apply ink efficiently and with excellent quality by pre-determining nozzles NZ which are to apply ink to a set or specific region based on the data.

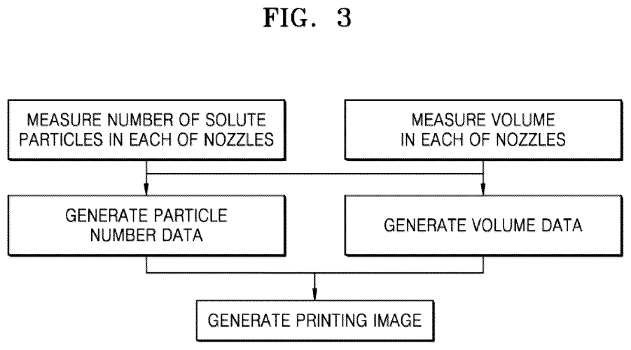

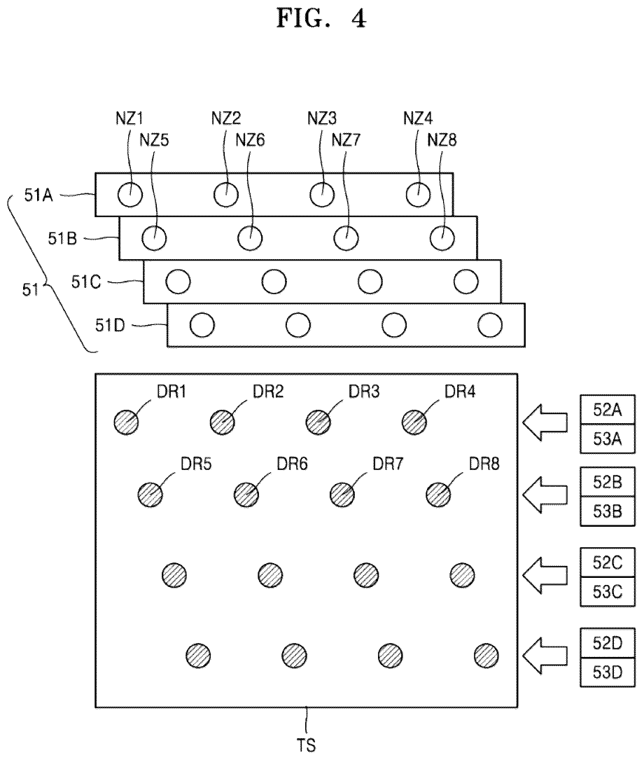

FIGS. 3-7 are diagrams schematically showing a method of manufacturing a display apparatus according to an embodiment. The method of manufacturing a display apparatus may employ the apparatus 2 for manufacturing a display apparatus, but is not necessarily limited thereto.

Referring to FIGS. 3-7, a droplet DR of ink may be discharged from each of the nozzles NZ of the head unit 51. In embodiments, the discharged droplet DR of the ink may be discharged on a test substrate TS. The controller 90 may measure the volumes of droplets DR and the number of solute particles within the droplets DR discharged on the test substrate TS by driving the particle number measuring unit 52 and the volume measuring unit 53. Hereinafter, droplets discharged by the first head unit 51A and the second head units 51B are mainly described. It may be understood that the same description applies to droplets discharged by the third head unit 51C and the fourth head unit 51D.

Nozzles of the first head unit 51A may be sequentially defined as a first nozzle NZ1 to a fourth nozzle NZ4. Nozzles of the second head units 51B may be sequentially defined as a fifth nozzle NZ5 to an eighth nozzle NZ8. Ink droplets discharged by the nozzles of the first head unit 51A, e.g., the first nozzle NZ1 to the fourth nozzle NZ4, may be sequentially defined as a first droplet DR1 to a fourth droplet DR4. Ink droplets discharged by the nozzles of the second head units 51B, e.g., the fifth nozzle NZ5 to the eighth nozzle NZ8, may be sequentially defined as a fifth droplet DR5 to an eighth droplet DR8. The first droplet DR1 to the fourth droplet DR4 may be measured by the first particle number measuring unit 52A. The first particle number measuring unit 52A may measure the number of solute particles, for example, functional particles, included in each of the first droplet DR1 to the fourth droplet DR4. The fifth droplet DR5 to the eighth droplet DR8 may be measured by the second particle number measuring unit 52B. The second particle number measuring unit 52B may measure the number of solute particles, for example, functional particles, included in each of the fifth droplet DR5 to the eighth droplet DR8. In embodiments, the volumes of the first droplet DR1 to the fourth droplet DR4 may be measured by the first volume measuring unit 53A. The volumes of the fifth droplet DR5 to the eighth droplet DR8 may be measured by the second volume measuring unit 53B.

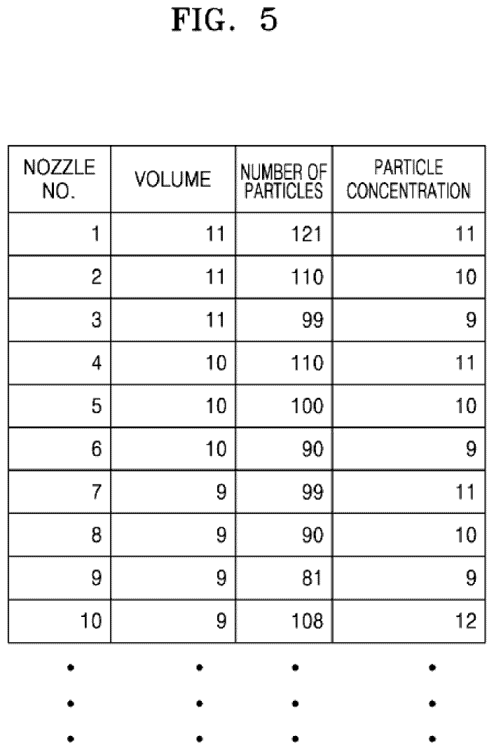

Referring to FIG. 5, the controller 90 may generate volume data and concentration data based on information obtained from the volume measuring unit 53 and the particle number measuring unit 52. For example, the controller 90 may generate volume data by matching the volume of each of the first droplet DR1 to the eighth droplet DR8 to a nozzle NZ that has applied the corresponding droplet. In embodiments, the controller 90 may generate particle number data by matching the number of solute particles in each of the first droplet DR1 to the eighth droplet DR8 to the nozzle NZ that has applied the corresponding droplet. Next, particle concentration may be defined as the number of solute particles within a droplet/the volume of the droplet, and thus, concentration data may be generated by using the volume data and the particle number data. Volume data, particle number data, and concentration data corresponding to each of nozzles are shown as examples in FIG. 5. The data of FIG. 5 is written as examples for convenience of explanation, and thus, it may be understood that units of volume and concentration are omitted.

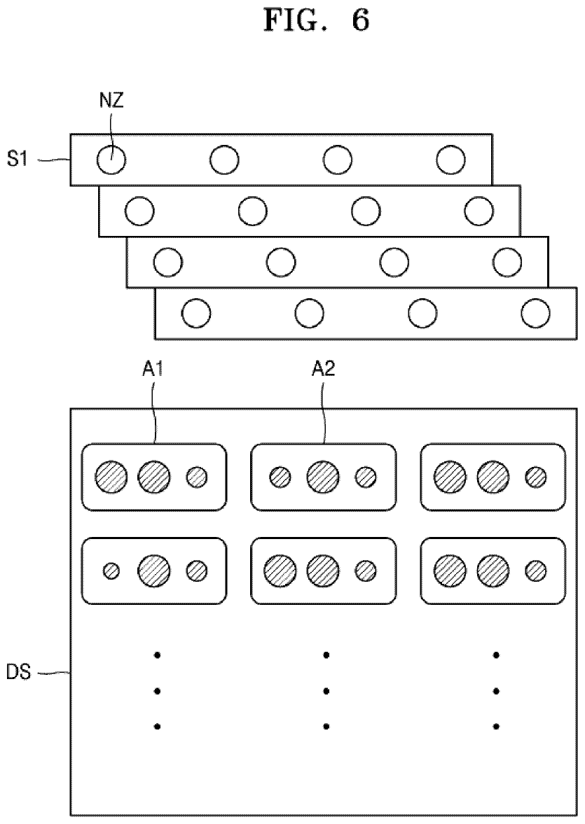

Referring to FIG. 6, the controller 90 may determine which nozzles NZ are to apply droplets to a printing region, from among a plurality of nozzles NZ. In more detail, the printing region is a region to which ink is applied, and in an embodiment, the printing region may correspond to an emission region of a pixel, and ink may be a material applied to form a color filter layer of the pixel. In embodiments, the printing region may correspond to an emission region of a pixel, and ink may be a material including quantum dots to form a functional layer of the pixel. In embodiments, the printing region may be provided as a plurality, and at least one nozzle may apply a droplet to each of a plurality of printing regions to fill each of the printing regions with ink. For example, the printing region may include a first region A1 and a second region A2. At least one nozzle NZ, for example, three nozzles NZ, may apply ink droplets to each of the first region A1 and the second region A2. However, this is for convenience of explanation, and the disclosure is not necessarily limited thereto, and three or more nozzles NZ or three or less nozzles NZ may apply ink droplets to each of the first region A1 and the second region A2. In embodiments, the number of nozzles NZ that apply ink droplets to each of the first region A1 and the second region A2 may be the same, but is not necessarily limited thereto and may be different.

The printing regions need to be coated with ink to have a uniform (e.g., substantially uniform) volume and a uniform (e.g., substantially uniform) number of solute particles to prevent mura (or to reduce a likelihood, degree, or occurrence of Mura). For example, to prevent mura (or to reduce a likelihood, degree, or occurrence of Mura), the volume of ink applied to each of the printing regions, for example, the first region A1 and the second region A2, may be made to be uniform (e.g., substantially uniform). In embodiments, the concentration of solute particles may vary for each of the nozzles NZ due to sedimentation of solute particles within the head unit 51 or non-uniformity in the flow rate of ink, and thus, it is useful or necessary to ensure uniformity (e.g., substantial uniformity) not only in the volume of ink applied to each of the printing regions, for example, the first region A1 and the second region A2, but also in the number of solute particles in the ink.

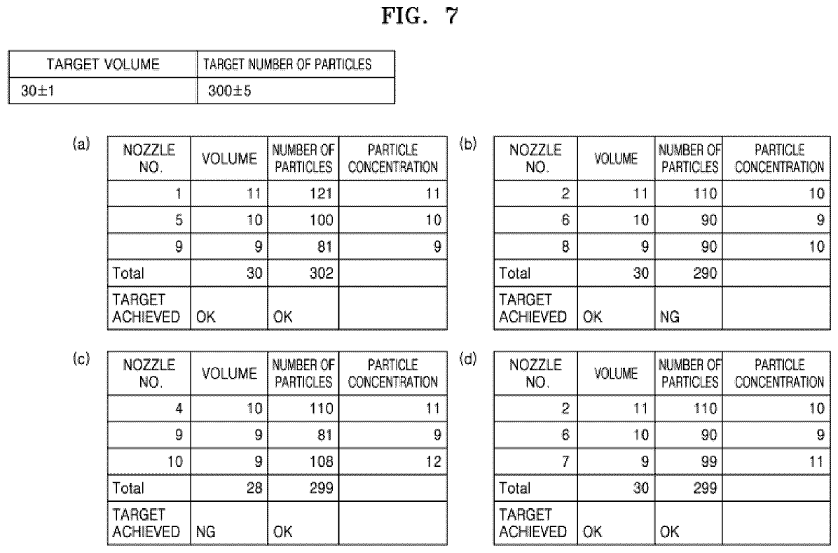

Referring additionally to FIG. 7, in an embodiment, the controller 90 may determine which nozzles NZ are to apply ink droplets to each of the printing regions, by considering at least one selected from among volume data, particle number data, and concentration data. In more detail, the controller 90 may have a preset target volume and a preset target number of particles. In this regard, the target volume may refer to a required volume of ink to be discharged into each of the printing regions, for example, the first region A1 and the second region A2. The target number of particles may refer to the number of solute particles required within ink to be discharged into each of the printing regions, for example, the first region A1 and the second region A2. FIG. 7 shows, as an example, a case where the target volume is 30 and the target number of particles is 300.

In embodiments, the controller 90 may have a preset tolerance for each of the target volume and the target number of particles. In this regard, the tolerance may refer to a degree of proximity to the target volume and the target number of particles, within which the target volume and the target number of particles are recognized as having been achieved. The tolerance may be set as a % or may be set as a unit of each of the target volume and the target number of particles. FIG. 7 shows, as an example, a case where the tolerance of the target volume is set to ±1 (e.g., ±1%) and the tolerance of the target number of particles is set to ±5 (e.g., ±5%).

Next, the controller 90 may determine nozzles NZ, for example, three nozzles NZ, which are to apply ink droplets to the first region A1, and the determined nozzles NZ may form a first nozzle group GN1. In embodiments, the controller 90 my select nozzles NZ to satisfy the target volume and the target number of particles. For example, the controller 90 may group any three nozzles NZ. In FIG. 7, (a) to (d) illustrate various suitable combinations of nozzles NZ. In embodiments, the controller 90 may select a combination of nozzles NZ, which allows the sum of the volumes of ink droplets discharged by three nozzles NZ to be at least 29 and not more than 31. In embodiments, the controller 90 may select a combination of nozzles NZ, which allows the sum of the numbers of solute particles included in ink droplets discharged by three nozzles NZ to be at least 295 and not more than 305. Each of (a) and (d) in FIG. 7 shows a case where nozzles are grouped to satisfy allowable requirements for the target volume and the target number of particles. For example, a first nozzle, a fifth nozzle, and a ninth nozzle, or a second nozzle, a sixth nozzle, and a seventh nozzle, satisfy the allowable requirements for the target volume and the target number of particles, and thus, one of the two combinations may form the first nozzle group GN1. In embodiments, the sum of volumes of respective ink droplets discharged by the nozzles of the first nozzle group GN1 may be the same as the target volume or may be within the range of tolerance of the target volume. In embodiments, the sum of the numbers of solute particles in respective droplets discharged by the nozzles of the first nozzle group GN1 may be the same as the target number of particles or may be within the range of tolerance of the target number of particles. As comparative examples, (b) of FIG. 7 illustrates a combination of nozzles, which satisfies the allowable requirement for the target volume, but does not satisfy the allowable requirement for the target number of particles, and (c) of FIG. 7 illustrates a combination of nozzles, which satisfies the allowable requirement for the target number of particles, but does not satisfy the allowable requirement for the target volume.

The controller 90 may determine any one of a combination (a) and a combination (d) as the first nozzle group GN1, and may control the first nozzle group GN1 to apply ink droplets to the first region A1.

In embodiments, the controller 90 may determine nozzles NZ, for example, three nozzles NZ, which are to apply ink droplets to the second region A2 in a similar manner, and the determined nozzles NZ may form a second nozzle group GN2. In the examples of FIG. 7, the controller 90 may determine, for example, the nozzles of the combination (d) as the second nozzle group GN2, and may control the second nozzle group GN2 to apply ink droplets to the second region A2. The controller 90 may form a combination of nozzles which are to apply ink to other printing regions, for example, a third region, a fourth region, and/or the like, in a similar manner. In embodiments, the controller 90 may pre-group nozzles which are to apply ink to each of the printing regions and determine a nozzle group before the spray unit 50 applies the ink. Based on this, the controller 90 may generate a printing image, and the spray unit 50 may apply the ink via the nozzles according to the printing image. In embodiments, if (e.g., when) the spray unit 50 applies ink, the controller 90 may group nozzles in real time and determine a nozzle group.

In embodiments, if (e.g., when) the controller 90 forms nozzle groups NZ, additional data may be taken into account. The additional data may be data about distances between nozzles and a printing region to be coated. For example, in the case of FIG. 7, combinations of nozzles, which satisfy the allowable requirements for the target volume and the target number of particles, may be (a) and (d). In embodiments, the controller 90 may form, as the first nozzle group GN1, the combination (a) consisting of nozzles NZ that are closer to the first region A1, and may form, as the second nozzle group GN2, the combination (d) consisting of nozzles NZ that are closer to the second region A2.

According to the embodiments as described above, the volume of ink applied to each of the printing regions may be uniform (e.g., substantially uniform), and the number of solute particles may be uniform. The controller 90 may select and determine a combination of nozzles, which satisfies the allowable requirements for the target volume and the target number of particles, from among a plurality of nozzles NZ. Accordingly, even though the nozzles have slightly different discharge volumes and discharge particle numbers, it is possible to ensure that each of the printing regions is uniformly (e.g., substantially uniformly) coated with ink, and thus, for example, mura related to the number of solute particles may be prevented (or a likelihood, degree, or occurrence of mura may be reduced).

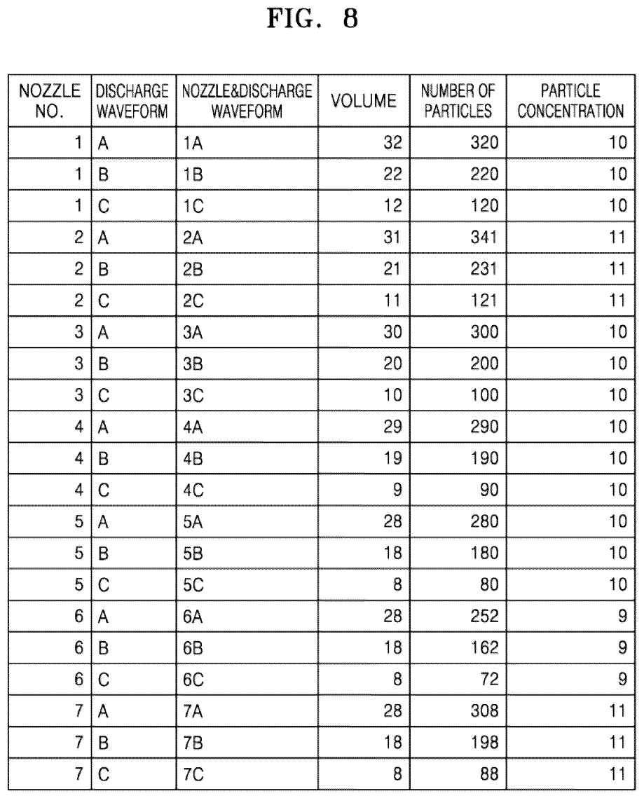

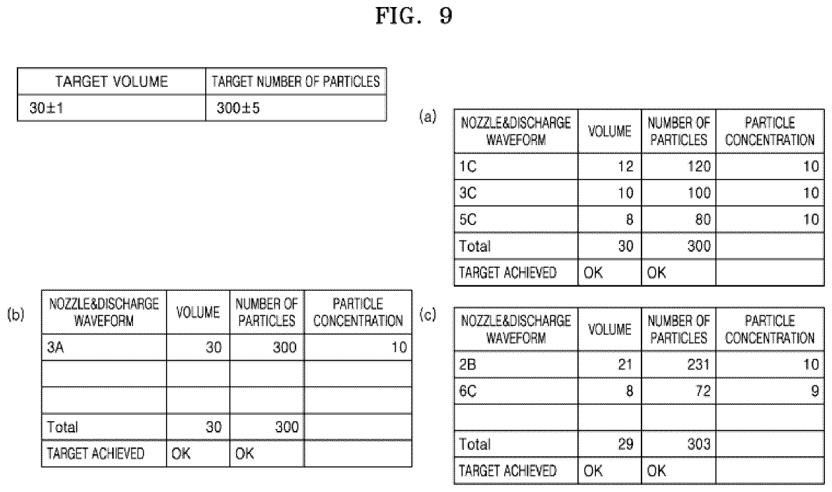

FIGS. 8-9 are diagrams schematically showing a method of manufacturing a display apparatus according to an embodiment. The manufacturing method according to the present embodiment is similar to the above-described manufacturing method, and thus, hereinafter, only differences are mainly described.

Referring to FIG. 8, in an embodiment, the controller 90 may generate volume data and particle number data by additionally considering discharge waveform information of nozzles NZ. For example, the controller 90 may receive discharge waveform information applicable to the nozzles NZ. The discharge waveform information is waveform information of a voltage applied to the head unit 51, and may include a plurality of different waveforms, for example, three waveforms that are a first waveform (A), a second waveform (B), and a third waveform (C). Each of the nozzles NZ may apply droplets according to different discharge waveforms, for example, the first waveform (A), the second waveform (B), and the third waveform (C), and respective droplets according to the discharge waveforms may have different volumes from each other even if (e.g., when) discharged from a same nozzle NZ.

Next, a droplet of ink may be discharged from each of the nozzles NZ of the head unit 51, and each of the nozzles NZ may discharge a droplet of ink according to a different voltage waveform of waveform information. At this time, in an embodiment, the discharged droplet of the ink may be discharged on a test substrate. Next, as described above, the controller 90 may measure the volumes of droplets and the number of solute particles within the droplets discharged on the test substrate by driving the particle number measuring unit 52 and the volume measuring unit 53. Volume data, particle number data, and concentration data of the droplets discharged in different waveforms by each of the nozzles, which are obtained in the above manner, are shown as examples in FIG. 8.

Referring to FIG. 9, the controller 90 may determine which nozzles NZ are to apply droplets to the printing region, from among the plurality of nozzles NZ. In an embodiment, the controller 90 may determine which nozzles NZ are to apply ink droplets to each of the printing regions, based on at least one selected from among the volume data, the particle number data, and the concentration data, which have taken the discharge waveform information into account. The controller 90 may group nozzles NZ to satisfy the allowable requirements for the above-described target volume and target number of particles. In embodiments, if (e.g., when) compared to the above-described embodiment, the controller 90 may additionally take the discharge waveform information into account. For example, (a) of FIG. 9 shows that a combination of a first nozzle discharged in the third waveform, a third nozzle discharged in the third waveform, and a fifth nozzle discharged in the third waveform satisfies the allowable requirements for the target volume and the target number of particles. In embodiments, (b) and (c) of FIG. 9 show that the number of nozzles NZ grouped to satisfy the requirements may be one or two, indicating that the number of nozzles NZ is not limited. The controller 90 may form a nozzle combination (a) into the first nozzle group GN1 to allow ink droplets to be applied to the first region A1. In embodiments, a nozzle combination (b) may be formed into the second nozzle group GN2 to allow ink droplets to be applied to the second region A2, and a nozzle combination (c) may be formed into a third nozzle group to allow ink droplets to be applied to the third region.

According to the embodiments as described above, the volume of ink applied to each of the printing regions may be uniform (e.g., substantially uniform), and the number of solute particles may be uniform (e.g., substantially uniform). Even if (e.g., when) printing a combination of different types (or kinds) of waveforms with different discharge volumes, information about the volumes of droplets to be discharged from nozzles and the number of solute particles is determined via measurement, and thus, the controller 90 may control to discharge ink into each of the printing regions such that the volumes and the number of solute particles are uniform.

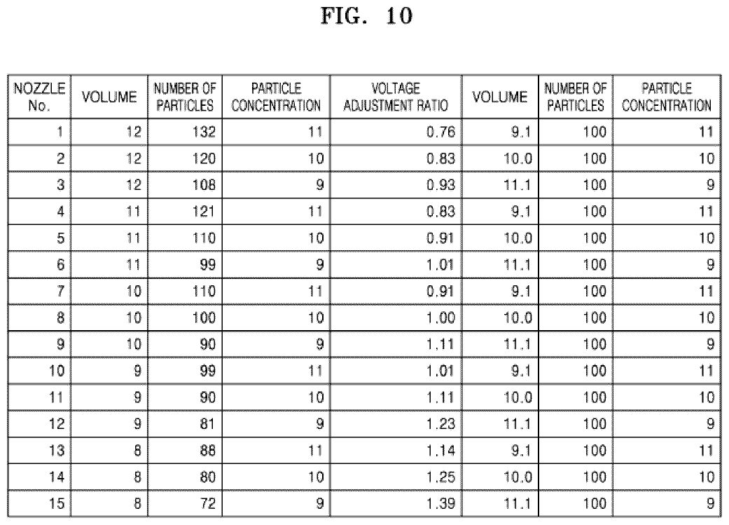

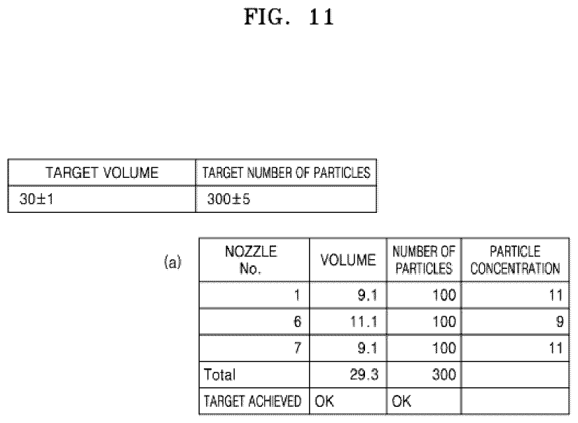

FIGS. 10-11 are diagrams schematically showing a method of manufacturing a display apparatus according to an embodiment. The manufacturing method according to the present embodiment is similar to the above-described manufacturing method, and thus, hereinafter, only differences are mainly described.

Referring to FIG. 10, in an embodiment, the controller 90 may adjust the volumes of droplets such that the numbers of solute particles in ink droplets discharged from nozzles NZ are the same. In more detail, ink droplets respectively discharged from each of a plurality of nozzles NZ may have different concentrations from each other. Therefore, the amount, e.g., the volume, of a droplet discharged from each of the nozzles NZ may be adjusted to ensure that the number of solute particles in each of the droplets is the same. To this end, in an embodiment, the head unit 51 may include a driver per nozzle (DPN) head. In embodiments, the head unit 51 may increase or decrease the volume of a droplet discharged by suitably varying a voltage applied to each of nozzles. For example, if (e.g., when) the voltage applied to each of the nozzles increases, each of the nozzles may discharge a droplet having a larger volume. If (e.g., when) the voltage applied to each of the nozzles decreases, each of the nozzles may discharge a droplet having a smaller volume.

The volume of a droplet discharged from each of the nozzles NZ, the concentration of a solute, and the number of solute particles have already been measured via the volume measuring unit 53 and the particle number measuring unit 52. Therefore, the controller 90 may change a voltage applied to the head unit 51, in embodiments, the nozzles NZ, to adjust a droplet discharge amount such that each of the nozzles NZ discharges a droplet having the same number of solute particles. Volume data, particle number data, and concentration data of droplets of respective nozzles, which are calculated in the above manner, are shown as examples in FIG. 10.

Referring to FIG. 11, the controller 90 may determine which nozzles NZ are to apply droplets to the printing region, from among the plurality of nozzles NZ. The controller 90 may group nozzles NZ to satisfy the allowable requirements for the above-described target volume and target number of particles. For example, a combination (a) of FIG. 11 shows that a combination of a first nozzle, a sixth nozzle, and a seventh nozzle, of which discharge volumes have been adjusted due to voltage adjustment, satisfies the allowable requirements for the target volume and the target number of particles. The controller 90 may form a nozzle combination (a) into the first nozzle group GN1 to allow ink droplets to be applied to the first region A1. In embodiments, it may be understood that ink droplets may be applied to another printing region, such as the second region A2, by additionally configuring a nozzle combination that satisfies the allowable requirements for the target volume and the target number of particles in the above manner.

According to the embodiments as described above, the volume of ink applied to each of the printing regions may be uniform (e.g., substantially uniform), and the number of solute particles may be uniform (e.g., substantially uniform). In more detail, information about discharge volume of each of nozzles and the number of solute particles in a droplet is determined via measurement, and thus, the discharge volume may be slightly adjusted such that the number of solute particles in the droplet discharged by each of the nozzles is the same. Accordingly, the number of solute particles in the droplet discharged by each of the nozzles is constant (e.g., substantially constant), and thus, the requirement for the target number of particles is easy to be satisfied, and only the requirement for the target volume needs to be considered. Therefore, the time for the controller 90 to group and select nozzles may be shortened.

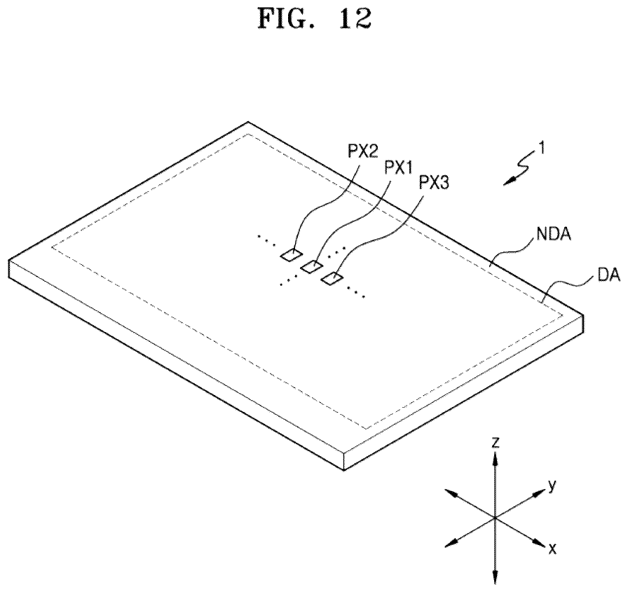

FIG. 12 is a perspective view schematically showing a display apparatus according to an embodiment.

Referring to FIG. 12, a display apparatus 1 may include a display region DA in which an image is implemented, and a non-display region NDA in which an image is not implemented. The display apparatus 1 may provide an image via an array of a plurality of sub-pixels two-dimensionally provided on an x-y plane of the display region DA. Each of the sub-pixels may emit light of different colors, and for example, may be one selected from among a red sub-pixel, a green sub-pixel, and a blue sub-pixel.

In an embodiment, the plurality of sub-pixels may include a first sub-pixel PX1, a second sub-pixel PX2, and a third sub-pixel PX3, and hereinafter, for convenience of explanation, an embodiment where the first sub-pixel PX1 is a red sub-pixel, the second sub-pixel PX2 is a green sub-pixel, and the third sub-pixel PX3 is a blue sub-pixel is described.

The first sub-pixel PX1, the second sub-pixel PX2, and the third sub-pixel PX3 may be regions that may emit red light Lr, green light Lg, and blue light Lb, respectively, and the display apparatus 1 may provide an image by using light emitted from the sub-pixels.

The non-display region NDA is a region that does not provide an image, and may entirely surround the display region DA. A driver or main voltage line for providing an electrical signal or power to pixel circuits may be provided in the non-display region NDA. The non-display region NDA may include a pad that is a region to which an electronic device or a printed circuit board may be electrically connected.

The display area DA may have a polygonal shape including a quadrangle as shown in FIG. 1. For example, the display region DA may have a rectangular shape in which a horizontal length is greater than a vertical length, or a rectangular shape in which a horizontal length is less than a vertical length, or may have a square shape. In embodiments, the display region DA may be a circle (e.g., generally a circle), an ellipse (e.g., generally an ellipse), or a polygon such as a triangle or a pentagon. In embodiments, the display apparatus 1 of FIG. 12 is a flat panel display apparatus, but the display apparatus 1 may be implemented in various suitable forms such as a flexible display apparatus, a foldable display apparatus, and/or a rollable display apparatus.

In an embodiment, the display apparatus 1 may be an organic light-emitting display apparatus. In embodiments, the display apparatus 1 may be an inorganic light-emitting display apparatus and/or a quantum dot light-emitting display apparatus. For example, an emission layer of a display element included in a display apparatus may include an organic material, an inorganic material, a quantum dot, an organic material and a quantum dot, an inorganic material and a quantum dot, or an organic material, an inorganic material, and a quantum dot. Hereinafter, for convenience of explanation, an embodiment where the display apparatus 1 is an organic light-emitting display apparatus is mainly described.

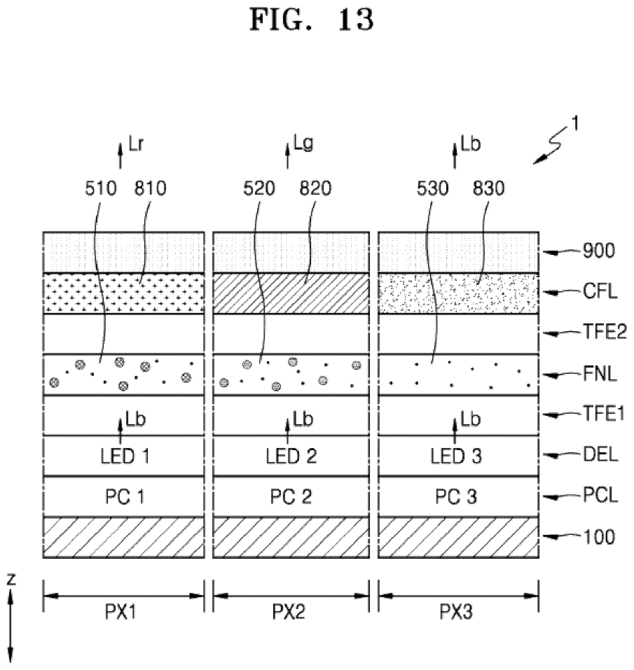

FIG. 13 is a cross-sectional view schematically showing the display apparatus 1 according to an embodiment.

Referring to FIG. 13, the display apparatus 1 may include a circuit layer PCL on a substrate 100. The circuit layer PCL may include first to third sub-pixel circuits PC1, PC2, and PC3 and an insulating layer (e.g., an electrically insulating layer or electrically insulating layers), and each of the first to third sub-pixel circuits PC1, PC2, and PC3 may include a thin-film transistor and/or a capacitor. A display element layer DEL may include first to third light-emitting diodes LED1, LED2, and LED3 as display elements. The first to third sub-pixel circuits PC1, PC2, and PC3 may be electrically connected to the first to third light-emitting diodes LED1, LED2, and LED3 of the display element layer DEL, respectively.

Each of the first to third light-emitting diodes LED1, LED2, and LED3 may be an organic light-emitting diode including an organic material. In embodiments, each of the first to third light-emitting diodes LED1, LED2, and LED3 may be an inorganic light-emitting diode including an inorganic material. The inorganic light-emitting diode may include a PN junction diode including inorganic semiconductor-based materials. If (e.g., when) a voltage is applied to a PN junction diode in a forward direction, holes and electrons are injected, and energy generated due to recombination of the holes and the electrons is converted to light energy so that light of a set or certain color may be emitted. The inorganic light-emitting diode may have a width of several to hundreds of micrometers, or several to hundreds of nanometers. In some embodiments, each of the first to third light-emitting diodes LED1, LED2, and LED3 may be a light-emitting diode including quantum dots. As described above, an emission layer of each of the first to third light-emitting diodes LED1, LED2, and LED3 may include an organic material, an inorganic material, quantum dots, an organic material and quantum dots, or an inorganic material and quantum dots.

The first to third light-emitting diodes LED1, LED2, and LED3 may emit light of the same color. For example, the first to third light-emitting diodes LED1, LED2, and LED3 may emit the blue light Lb. However, the disclosure is not limited thereto. In embodiments, the first to third light-emitting diodes LED1, LED2, and LED3 may emit light of different colors. Light (for example, the blue light Lb) emitted from the first to third light-emitting diodes LED1, LED2, and LED3 may pass through a first thin-film encapsulation layer TFE1 on the display element layer DEL and a functional layer FNL.

The functional layer FNL may include optical layers that convert or do not convert a color of light (for example, the blue light Lb) emitted from the display element layer DEL and transmit the light. For example, the functional layer FNL may include quantum dot layers that convert light (for example, the blue light Lb) emitted from the display element layer DEL into light of a different color, and a transmissive layer that does not convert color of light (for example, the blue light Lb) emitted from the display element layer DEL and transmits the light. The functional layer FNL may include a first quantum dot layer 510 corresponding to the first sub-pixel PX1, a second quantum dot layer 520 corresponding to the second sub-pixel PX2, and a transmissive layer 530 corresponding to the third sub-pixel PX3. The first quantum dot layer 510 may convert the blue light Lb into the red light Lr, and the second quantum dot layer 520 may convert the blue light Lb into the green light Lg. The transmissive layer 530 may transmit the blue light Lb without conversion.

A color filter CFL may be on the functional layer FNL. A second thin-film encapsulation layer TFE2 may be between the functional layer FNL and the color filter CFL. The color filter CFL may include first to third color filters 810, 820, and 830 of different colors. In an embodiment, the first color filter 810 may be a red color filter, the second color filter 820 may be a green color filter, and the third color filter 830 may be a blue color filter.

Each of the color-converted light and transmitted light from the functional layer FNL may have improved color impurity by passing through the first to third color filters 810, 820, and 830. In embodiments, the color filter CFL may prevent, minimize, or reduce reflection of external light (for example, light incident from the outside of the display apparatus 1 toward the display apparatus 1) and visibility thereof to a user.

An overcoat layer 900 may be on the color filter CFL. The overcoat layer 900 may include an organic material. For example, the overcoat layer 900 may include a light-transmissive organic material such as acrylic resin.

In an embodiment, after the functional layer FNL, the second thin-film encapsulation layer TFE2, and the color filter CFL are sequentially formed on the first thin-film encapsulation layer TFE1, the overcoat layer 900 may be formed by being directly applied and cured on the color filter CFL. In some embodiments, another optical film, for example, an anti-reflection (AR) film, may be on the overcoat layer 900. In some embodiments, a window may be further on the overcoat layer 900.

The display apparatus 1 having the structure described above may include an electronic device capable of displaying a moving image and/or a still image, such as a television, a billboard, a movie theater screen, a monitor, a tablet PC, a laptop, and/or the like.

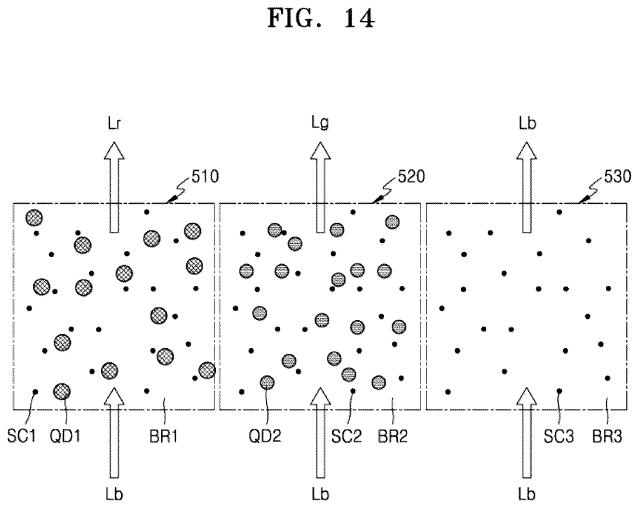

FIG. 14 shows each of optical layers of a functional layer of FIG. 13.

Referring to FIG. 14, the first quantum dot layer 510 may convert incoming blue light Lb into the red light Lr. As shown in the drawing, the first quantum dot layer 510 may include a first photosensitive polymer BR1, first quantum dots QD1, and first scattering particles SC1, wherein the first quantum dots QD1 and the first scattering particles SC1 are dispersed in the first photosensitive polymer BR1.

The first quantum dots QD1 may be excited by the blue light Lb and isotropically emit the red light Lr having a longer wavelength than the wavelength of the blue light Lb. The first photosensitive polymer BR1 may be a light-transmissive organic material. The first scattering particles SC1 may scatter the blue light Lb that is not absorbed by the first quantum dots QD1, thereby allowing more first quantum dots QD1 to be excited and increasing color conversion efficiency. The first scattering particles SC1 may be, for example, titanium oxide (TiO₂) and/or metal particles. The first quantum dots QD1 may be selected from a Group II-VI compound, a Group III-V compound, a Group IV-VI compound, a Group IV element, a Group IV compound, and a combination thereof.

The second quantum dot layer 520 may convert incoming blue light Lb into the green light Lg. As shown in the drawing, the second quantum dot layer 520 may include a second photosensitive polymer BR2, second quantum dots QD2, and second scattering particles SC2, wherein the second quantum dots QD2 and the second scattering particles SC2 are dispersed in the second photosensitive polymer BR2.

The second quantum dots QD2 may be excited by the blue light Lb and isotropically emit the green light Lg having a longer wavelength than the wavelength of the blue light Lb. The second photosensitive polymer BR2 may be a light-transmissive organic material.

The second scattering particles SC2 may scatter the blue light Lb that is not absorbed by the second quantum dots QD2, thereby allowing more second quantum dots QD2 to be excited and increasing color conversion efficiency. The second scattering particles SC2 may be, for example, titanium oxide (TiO₂) and/or metal particles. The second quantum dots QD2 may be selected from a Group II-VI compound, a Group III-V compound, a Group IV-VI compound, a Group IV element, a Group IV compound, and a combination thereof.

In some embodiments, the first quantum dots QD1 and the second quantum dots QD2 may include the same material. In embodiments, the size of the second quantum dots QD2 may be greater than the size of the first quantum dots QD1.

The transmissive layer 530 may transmit the blue light Lb without converting the blue light Lb incident on the transmissive layer 530. As shown in the drawing, the transmissive layer 530 may include a third photosensitive polymer BR3 in which third scattering particles SC3 are dispersed. The third photosensitive polymer BR3 may be, for example, a light-transmissive organic material such as silicon resin, epoxy resin, and/or the like, and may include the same material as the first and second photosensitive polymers BR1 and BR2. The third scattering particles SC3 may scatter and emit the blue light Lb and may include the same material as the first and second scattering particles SC1 and SC2.

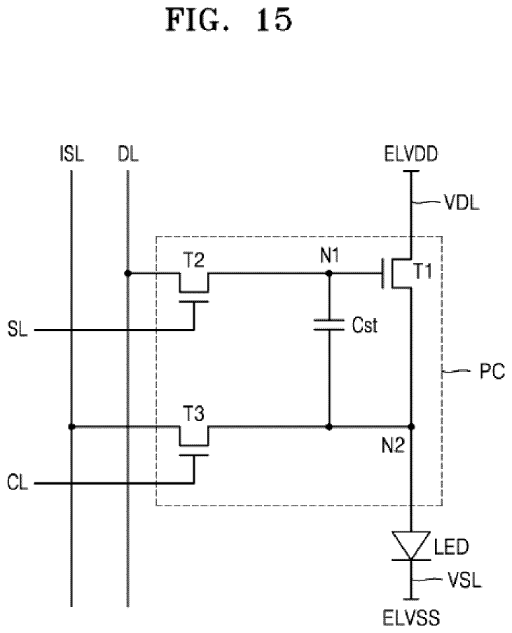

FIG. 15 is an equivalent circuit diagram showing a light-emitting diode included in a display apparatus according to an embodiment and a sub-pixel circuit electrically connected to the light-emitting diode. A sub-pixel circuit PC shown in FIG. 15 may corresponds to each of the first to third sub-pixel circuits PC1, PC2, and PC3 described above with reference to FIG. 13, and a light-emitting diode LED in FIG. 15 may correspond to each of the first to third light-emitting diodes LED1, LED2, and LED3 described above with reference to FIG. 13.

Referring to FIG. 15, a sub-pixel electrode (for example, an anode) of a light-emitting diode, for example, the light-emitting diode LED, may be connected to the sub-pixel circuit PC, and an opposite electrode (for example, a cathode) of the light-emitting diode LED may be connected to a common voltage line VSL that is configured to provide a common voltage ELVSS, or an auxiliary wiring. The light-emitting diode LED may emit light having a luminance corresponding to the amount of current supplied from the sub-pixel circuit PC.

The sub-pixel circuit PC may be configured to control the amount of current flowing from a driving voltage ELVDD to the common voltage ELVSS via the light-emitting diode LED in correspondence with a data signal. The sub-pixel circuit PC may include a first thin-film transistor T1, a second thin-film transistor T2, a third thin-film transistor T3, and a storage capacitor Cst.

Each of the first thin-film transistor T1, the second thin-film transistor T2, and the third thin-film transistor T3 may be an oxide semiconductor transistor including a semiconductor layer including an oxide semiconductor, or may be a silicon semiconductor transistor including a semiconductor layer including polysilicon. According to the type (or kind) of thin-film transistor, a first electrode may be one selected from among a source electrode and a drain electrode, and a second electrode may be the other one selected from among the source electrode and the drain electrode.

The first thin-film transistor T1 may be a driving thin-film transistor. A first electrode of the first thin-film transistor T1 may be connected to a driving voltage line VDL that is configured to supply the driving voltage ELVDD, and a second electrode of the first thin-film transistor T1 may be connected to the sub-pixel electrode of the light-emitting diode LED. A gate electrode of the first thin-film transistor T1 may be connected to a first node N1. The first thin-film transistor T1 may be configured to control the amount of current flowing from the driving voltage ELVDD to the light-emitting diode LED in correspondence with a voltage at the first node N1.

The second thin-film transistor T2 may be a switching thin-film transistor. A first electrode of the second thin-film transistor T2 may be connected to a data line DL, and a second electrode of the second thin-film transistor T2 may be connected to the first node N1. A gate electrode of the second thin-film transistor T2 may be connected to a scan line SL. The second thin-film transistor T2 may be turned on if (e.g., when) a scan signal is supplied to the scan line SL, and may be configured to electrically connect the data line DL and the first node N1 together.

The third thin-film transistor T3 may be an initialization thin-film transistor and/or a sensing thin-film transistor. A first electrode of the third thin-film transistor T3 may be connected to a second node N2, and a second electrode of the third thin-film transistor T3 may be connected to a sensing line ISL. A gate electrode of the third thin-film transistor T3 may be connected to a control line CL.

The storage capacitor Cst may be connected between the first node N1 and the second node N2. For example, a first capacitor electrode of the storage capacitor Cst may be connected to the gate electrode of the first thin-film transistor T1, and a second capacitor electrode of the storage capacitor Cst may be connected to the sub-pixel electrode of the light-emitting diode LED.

FIG. 15 shows that each of the first thin-film transistor T1, the second thin-film transistor T2, and the third thin-film transistor T3 is an NMOS transistor, but the disclosure is not limited thereto. For example, at least one selected from among the first thin-film transistor T1, the second thin-film transistor T2, and the third thin-film transistor T3 may be formed as a PMOS transistor.

Three transistors are shown in FIG. 15, but the disclosure is not limited thereto. The sub-pixel circuit PC may include at least four thin-film transistors.

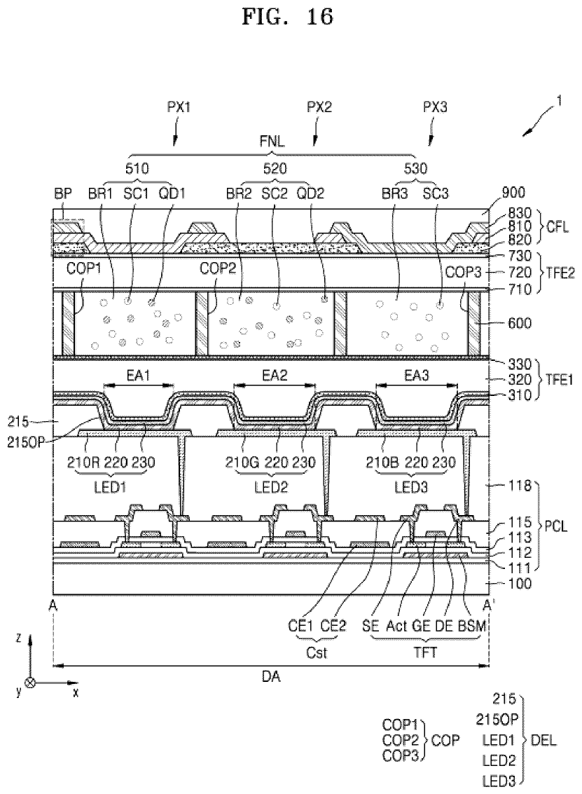

FIG. 16 is a cross-sectional view schematically showing the display apparatus according to an embodiment. Referring to FIG. 16, the display apparatus 1 may include the first sub-pixel PX1, the second sub-pixel PX2, and the third sub-pixel PX3, which emit different colors, and for example, the first sub-pixel PX1 may implement the red light Lr, the second sub-pixel PX2 may implement the green light Lg, and the third sub-pixel PX3 may implement the blue light Lb.

The display apparatus 1 may include a structure of a stack of the substrate 100, the circuit layer PCL, the display element layer DEL, a lower color filter 400, the functional layer FNL, and the color filter CFL, wherein the circuit layer PCL, the display element layer DEL, the lower color filter 400, the functional layer FNL, and the color filter CFL are on the substrate 100. The display element layer DEL may include the first to third light-emitting diodes LED1, LED2, and LED3 electrically connected to sub-pixel circuits of the circuit layer PCL. The circuit layer PCL may include a plurality of sub-pixel circuits respectively corresponding to first to third sub-pixels PX1, PX2, and PX3, and each of the plurality of sub-pixel circuits may include a plurality of thin-film transistors TFT and the storage capacitor Cst as described with reference to FIG. 15. For example, each of the plurality of thin-film transistors TFT may be the driving thin-film transistor T1 (FIG. 15).

The substrate 100 may include glass and/or polymer resin. In embodiments, the polymer resin may include at least one selected from among polyethersulfone, polyarylate, polyether imide, polyethylene naphthalate, polyethylene terephthalate, polyphenylene sulfide, polyimide, polycarbonate, cellulose triacetate, and cellulose acetate propionate. The substrate 100 may have a single-layer or multilayer structure including the above-described material. In an embodiment, the substrate 100 may have a structure of an organic material/inorganic material/organic material.

The circuit layer PCL may be on the substrate 100. FIG. 16 shows that the circuit layer PCL includes the thin-film transistor TFT, the storage capacitor Cst, a first buffer layer 111, a second buffer layer 112, a gate insulating layer 113, an interlayer insulating layer 115, and a planarization layer 118, wherein the first buffer layer 111, the second buffer layer 112, the gate insulating layer 113, the interlayer insulating layer 115, and the planarization layer 118 are under and/or above the thin-film transistor TFT and the storage capacitor Cst.

The first buffer layer 111 and the second buffer layer 112 may reduce or block penetration of foreign substances, moisture, and/or external air from under the substrate 100. The first buffer layer 111 and the second buffer layer 112 may include an inorganic insulating material (e.g., an inorganic electrically insulating material) such as silicon nitride, silicon oxynitride, and/or silicon oxide, and may be a single layer or a multilayer, which includes the above-described inorganic insulating material.

A bias electrode BSM may be on the first buffer layer 111 to correspond to the thin-film transistor TFT. In an embodiment, a voltage may be applied to the bias electrode BSM. Also, the bias electrode BSM may prevent or reduce incidence of external light on a semiconductor layer Act. Accordingly, characteristics of the thin-film transistor TFT may be stabilized. In some embodiments, the bias electrode BSM may be omitted.

The semiconductor layer Act may be on the second buffer layer 112. The semiconductor layer Act may include amorphous silicon or polysilicon. In embodiments, the semiconductor layer Act may include an oxide of at least one material selected from the group including indium (In), gallium (Ga), tin (Sn), zirconium (Zr), vanadium (V), hafnium (Hf), cadmium (Cd), germanium (Ge), chromium (Cr), titanium (Ti), aluminum (Al), cesium (Cs), cerium (Ce), and zinc (Zn). In some embodiments, the semiconductor layer Act may include Zn oxide, In—Zn oxide, and/or Ga—In—Zn oxide, as a Zn-oxide-based material. In some embodiments, the semiconductor layer Act may be an In—Ga—Zn—O (IGZO), In—Sn—Zn—O (ITZO), and/or In—Ga—Sn—Zn—O (IGTZO) semiconductor containing a metal such as indium (In), gallium (Ga), and/or tin (Sn) in ZnO. The semiconductor layer Act may include a channel region, a source region, and a drain region, wherein the source region and the drain region are respectively provided at both sides of the channel region. A gate electrode GE may overlap the channel region of the semiconductor layer Act.

The gate electrode GE may include a low-resistance metal material (e.g., a low-electrical-resistance metal material). The gate electrode GE may include a conductive material (e.g., an electrically conductive material) such as molybdenum (Mo), aluminum (Al), copper (Cu), titanium (Ti), and/or the like, and may be formed as a single layer or a multilayer, which includes the above-described material.

The gate insulating layer 113 may be between the semiconductor layer Act and the gate electrode GE. The gate insulating layer 113 may include an inorganic insulating material (e.g., an inorganic electrically insulating material) such as silicon oxide, silicon nitride, silicon oxynitride, aluminum oxide, titanium oxide, tantalum oxide, hafnium oxide, and/or zinc oxide.

A first electrode CE1 of the storage capacitor Cst may be on the same layer as the gate electrode GE. The first electrode CE1 may be include the same material as the gate electrode GE. FIG. 16 shows that the gate electrode GE of the thin-film transistor TFT and the first electrode CE1 of the storage capacitor Cst are spaced apart from each other, but in embodiments, the storage capacitor Cst may overlap the thin-film transistor TFT. In embodiments, the gate electrode GE of the thin-film transistor TFT may function as the first electrode CE1 of the storage capacitor Cst.

The interlayer insulating layer 115 may cover the gate electrode GE. The interlayer insulating layer 115 may include an inorganic insulating material (e.g., an inorganic electrically insulating material) such as silicon oxide, silicon nitride, silicon oxynitride, aluminum oxide, titanium oxide, tantalum oxide, hafnium oxide, and/or zinc oxide.

A second electrode CE2 of the storage capacitor Cst, a source electrode SE, and a drain electrode DE may be above the interlayer insulating layer 115.

The second electrode CE2 of the storage capacitor Cst, the source electrode SE, and the drain electrode DE may include a conductive material (e.g., an electrically conductive material) including molybdenum (Mo), aluminum (Al), copper (Cu), titanium (Ti), and/or the like, and may be formed as a single layer or a multilayer, which includes the above-described material. For example, the second electrode CE2 of the storage capacitor Cst, the source electrode SE, and the drain electrode DE may have a multilayer structure of Ti/Al/Ti. The source electrode SE and the drain electrode DE may be connected to the source region or the drain region of the semiconductor layer Act via a contact hole.

The second electrode CE2 of the storage capacitor Cst may overlap the first electrode CE1 with the interlayer insulating layer 115 therebetween, and the first electrode CE1 and the second electrode CE2 may form the storage capacitor Cst. In embodiments, the interlayer insulating layer 115 may function as a dielectric layer of the storage capacitor Cst.

The planarization layer 118 may cover the second electrode CE2 of the storage capacitor Cst, the source electrode SE, and the drain electrode DE. The planarization layer 118 may be formed as a single layer or a multilayer, which includes an organic material, and may provide a flat top surface. The planarization layer 118 may include a general-purpose polymer such as benzocyclobutene (BCB), polyimide, hexamethyldisiloxane (HMDSO), polymethylmethacrylate (PMMA), and/or polystyrene (PS), a polymer derivative having a phenol-based group, an acrylic polymer, an imide-based polymer, an aryl ether-based polymer, an amide-based polymer, a fluorine-based polymer, a p-xylene-based polymer, a vinyl alcohol-based polymer, and/or a blend thereof.

The display element layer DEL may be on the circuit layer PCL having the above-described structure. The display element layer DEL may include the first to third light-emitting diodes LED1, LED2, and LED3, which are organic light-emitting diodes, as display elements. The first light-emitting diode LED1, the second light-emitting diode LED2, and the third light-emitting diode LED3 may respectively include a first sub-pixel electrode 210R, a second sub-pixel electrode 210G, and a third sub-pixel electrode 210B. In an embodiment, the first light-emitting diode LED1, the second light-emitting diode LED2, and the third light-emitting diode LED3 may commonly include an emission layer 220 and an opposite electrode 230.

Each of the first sub-pixel electrode 210R, the second sub-pixel electrode 210G, and the third sub-pixel electrode 210B may be a (semi) light-transmissive electrode or a reflective electrode. In some embodiments, the first sub-pixel electrode 210R, the second sub-pixel electrode 210G, and the third sub-pixel electrode 210B may include a conductive oxide (e.g., an electrically conductive oxide), such as indium tin oxide (ITO), indium zinc oxide (IZO), zinc oxide (ZnO), indium oxide (In₂O₃), indium gallium oxide (IGO), and/or aluminum zinc oxide (AZO). In an embodiment, each of the first sub-pixel electrode 210R, the second sub-pixel electrode 210G, and the third sub-pixel electrode 210B may include a reflective film including silver (Ag), magnesium (Mg), aluminum (Al), platinum (Pt), palladium (Pd), gold (Au), nickel (Ni), neodymium (Nd), iridium (Ir), chromium (Cr), and/or a compound thereof. In embodiments, a film including ITO, IZO, ZnO, and/or In₂O₃ may be further included above and/or under the above-described film. For example, each of the first sub-pixel electrode 210R, the second sub-pixel electrode 210G, and the third sub-pixel electrode 210B may be provided as ITO/Ag/ITO.

A first bank layer 215 may be on the planarization layer 118. The first bank layer 215 may include openings 215OP that respectively expose central portions of the first sub-pixel electrode 210R, the second sub-pixel electrode 210G, and the third sub-pixel electrode 210B. The first bank layer 215 may cover each of edges of the first sub-pixel electrode 210R, the second sub-pixel electrode 210G, and the third sub-pixel electrode 210B. The first bank layer 215 may prevent an arc and/or the like from occurring at the edges of the first sub-pixel electrode 210R, the second sub-pixel electrode 210G, and the third sub-pixel electrode 210B (or reduce a likelihood, degree, or occurrence thereof) by increasing a distance between the edges of the first sub-pixel electrode 210R, the second sub-pixel electrode 210G, and the third sub-pixel electrode 210B and the opposite electrode 230 above the first sub-pixel electrode 210R, the second sub-pixel electrode 210G, and the third sub-pixel electrode 210B.

The first bank layer 215 may be at least one organic insulating material (e.g., an organic electrically insulating material) selected from the group consisting of polyimide, polyamide, acrylic resin, benzocyclobutene, and phenol resin.

The emission layer 220 of the first light-emitting diode LED1, the second light-emitting diode LED2, and the third light-emitting diode LED3 may include an organic material including a fluorescent and/or phosphorescent material that emits red light, green light, blue light, or white light. The emission layer 220 may be a low-molecular-weight organic material and/or a polymer organic material, and an additional functional layer such as a hole transport layer (HTL), a hole injection layer (HIL), an electron transport layer (ETL), and an electron injection layer (EIL) may be selectively provided under and above the emission layer 220. As shown in FIG. 16, the emission layer 220 may be formed integrally across the first sub-pixel electrode 210R, the second sub-pixel electrode 210G, and the third sub-pixel electrode 210B, but the disclosure is not limited thereto. In some embodiments, the emission layer 220 may include a layer patterned to correspond to each of the first sub-pixel electrode 210R, the second sub-pixel electrode 210G, and the third sub-pixel electrode 210B. In embodiments, the emission layer 220 may be a first-color emission layer. The first-color emission layer may emit light in a first wavelength band, and for example, may emit blue light. In an embodiment, the emission layer 220 may emit light having a wavelength of about 450 nm to about 495 nm.

The opposite electrode 230 may be on the emission layer 220 and may correspond to the first sub-pixel electrode 210R, the second sub-pixel electrode 210G, and the third sub-pixel electrode 210B. The opposite electrode 230 may be formed integrally across the first sub-pixel electrode 210R, the second sub-pixel electrode 210G, and the third sub-pixel electrode 210B. In an embodiment, the opposite electrode 230 may include a conductive material (e.g., an electrically conductive material) having a low work function. For example, the opposite electrode 230 may include a (semi) transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), and/or an alloy thereof. In embodiments, the opposite electrode 230 may further include a layer including ITO, IZO, ZnO, and/or In₂O₃ on the (semi) transparent layer including the above-described material.

First to third emission regions EA1, EA2, and EA3 may respectively correspond to the first to third sub-pixels PX1, PX2, and PX3. The first to third emission regions EA1, EA2, and EA3 may be regions in which light generated by the first to third light-emitting diodes LED1, LED2, and LED3 is emitted to the outside. The first emission region EA1 may be defined as a portion of the first sub-pixel electrode 210R, which is exposed by the opening 215OP in the first bank layer 215. The second emission region EA2 may be defined as a portion of the second sub-pixel electrode 210G, which is exposed by the opening 215OP in the first bank layer 215. The third emission region EA3 may be defined as a portion of the third sub-pixel electrode 210B, which is exposed by the opening 215OP in the first bank layer 215. In embodiments, each of the first emission region EA1, the second emission region EA2, and the third emission region EA3 may be defined by their respective openings 215OP in the first bank layer 215.

The first emission region EA1, the second emission region EA2, and the third emission region EA3 may be spaced apart from each other. A region other than the first emission region EA1, the second emission region EA2, and the third emission region EA3 in the display region DA may be a non-emission region. The first emission region EA1, the second emission region EA2, and the third emission region EA3 may be distinguished by the non-emission region.

A spacer to prevent mask scratches (or to reduce a likelihood, a degree, or an occurrence thereof) may be further included on the first bank layer 215. In an embodiment, the spacer and the first bank layer 215 may be integrally formed as a single body. For example, the spacer and the first bank layer 215 may be concurrently (e.g., simultaneously) formed in the same process by using a halftone mask process.

The first thin-film encapsulation layer TFE1 may cover the display element layer DEL. The first light-emitting diode LED1, the second light-emitting diode LED2, and the third light-emitting diode LED3 may be easily damaged by moisture and/or oxygen introduced from the outside, and thus may be protected by being covered with the first thin-film encapsulation layer TFE1. The first thin-film encapsulation layer TFE1 may cover the display region DA and may extend to the outside of the display region DA. The first thin-film encapsulation layer TFE1 may include at least one organic encapsulation layer and at least one inorganic encapsulation layer. For example, the first thin-film encapsulation layer TFE1 may include a first inorganic encapsulation layer 310, a first organic encapsulation layer 320, and a second inorganic encapsulation layer 330, which are sequentially stacked.

The first inorganic encapsulation layer 310 and the second inorganic encapsulation layer 330 may include at least one inorganic material selected from among aluminum oxide, titanium oxide, tantalum oxide, hafnium oxide, zinc oxide, silicon oxide, silicon nitride, and silicon oxynitride. The first organic encapsulation layer 320 may include a polymer-based material. The polymer-based material may include acrylic resin, epoxy-based resin, polyimide, and/or polyethylene. In an embodiment, the first organic encapsulation layer 320 may include acrylate. The first organic encapsulation layer 320 may be formed by curing a monomer and/or applying a polymer.

The first thin-film encapsulation layer TFE1 has the above-described multilayer structure, and thus, even if (e.g., when) a crack occurs in the first thin-film encapsulation layer TFE1, it is possible to prevent or reduce propagation of the crack between the first inorganic encapsulation layer 310 and the first organic encapsulation layer 320 and/or between the first organic encapsulation layer 320 and the second inorganic encapsulation layer 330. Formation of a path via which moisture and/or oxygen from the outside penetrates into the display region DA may be prevented, minimized, or reduced.

In some embodiments, other layers such as a capping layer may be further between the first inorganic encapsulation layer 310 and the opposite electrode 230.

A second bank layer 600 may be on the first thin-film encapsulation layer TFE1. The second bank layer 600 may include an organic material and/or an inorganic material. For example, the second bank layer 600 may include an inorganic material such as silicon oxide, silicon nitride, and/or silicon oxynitride. In some embodiments, the second bank layer 600 may include a light-blocking material to function as a light-blocking layer. The light-blocking material may include, for example, at least one selected from among a black pigment, a black dye, black particles, and/or metal particles.

In the second bank layer 600, openings COP may be defined by partition walls. A first opening COP1 in the second bank layer 600 may correspond to the opening 215OP that exposes the first sub-pixel electrode 210R of the first bank layer 215, a second opening COP2 in the second bank layer 600 may correspond to the opening 215OP that exposes the second sub-pixel electrode 210G of the first bank layer 215, and a third opening COP3 in the second bank layer 600 may correspond to the opening 215OP that exposes the third sub-pixel electrode 210B of the first bank layer 215. In embodiments, if (e.g., when) viewed in a direction (z-axis direction) perpendicular to the substrate 100, the first opening COP1 in the second bank layer 600 may overlap the opening 215OP that exposes the first sub-pixel electrode 210R of the first bank layer 215, the second opening COP2 in the second bank layer 600 may overlap the opening 215OP that exposes the second sub-pixel electrode 210G of the first bank layer 215, and the third opening COP3 in the second bank layer 600 may overlap the opening 215OP that exposes the second sub-pixel electrode 210G of the first bank layer 215. A partition wall may be between the first opening COP1, the second opening COP2, and the third opening COP3 in the second bank layer 600.

The functional layer FNL may occupy the openings COP in the second bank layer 600. In an embodiment, the functional layer FNL may include at least one selected from among quantum dots and scattering particles (e.g., light scattering particles). The functional layer FNL may include the first quantum dot layer 510, the second quantum dot layer 520, and the transmissive layer 530.

The first quantum dot layer 510 may occupy the first opening COP1 in the second bank layer 600. The first quantum dot layer 510 may overlap the first emission region EA1. The first sub-pixel PX1 may include the first light-emitting diode LED1 and the first quantum dot layer 510.

The first quantum dot layer 510 may convert the light in the first wavelength band, which has been generated from the emission layer 220 on the first sub-pixel electrode 210R, into light in a second wavelength band. The first quantum dot layer 510 may convert blue light into red light. For example, if (e.g., when) light having a wavelength of about 450 nm to about 495 nm is generated from the emission layer 220 on the first sub-pixel electrode 210R, the first quantum dot layer 510 may convert the light into light having a wavelength of about 630 nm to about 780 nm. Therefore, in the first sub-pixel PX1, the light having the wavelength of about 630 nm to about 780 nm may be emitted to the outside.

The first quantum dot layer 510 may include the first photosensitive polymer BR1, the first quantum dots QD1, and the first scattering particles SC1, wherein the first quantum dots QD1 and the first scattering particles SC1 are dispersed in the first photosensitive polymer BR1.

The second quantum dot layer 520 may occupy the second opening COP2 in the second bank layer 600. The second quantum dot layer 520 may overlap the second emission region EA2. The second sub-pixel PX2 may include the second light-emitting diode LED2 and the second quantum dot layer 520.

The second quantum dot layer 520 may convert the light in the first wavelength band, which has been generated from the emission layer 220 on the second sub-pixel electrode 210G, into light in a third wavelength band. The second quantum dot layer 520 may convert blue light into green light. For example, if (e.g., when) light having a wavelength of about 450 nm to about 495 nm is generated from the emission layer 220 on the second sub-pixel electrode 210G, the second quantum dot layer 520 may convert the light into light having a wavelength of about 495 nm to about 570 nm. Therefore, in the second sub-pixel PX2, the light having the wavelength of about 495 nm to about 570 nm may be emitted to the outside.

The second quantum dot layer 520 may include the second photosensitive polymer BR2, the second quantum dots QD2, and the second scattering particles SC2, wherein the second quantum dots QD2 and the second scattering particles SC2 are dispersed in the second photosensitive polymer BR2.

The transmissive layer 530 may occupy the third opening COP3 in the second bank layer 600. The transmissive layer 530 may overlap the third emission region EA3. The third sub-pixel PX3 may include the third light-emitting diode LED3 and the transmissive layer 530.

The transmissive layer 530 may emit, to the outside, light generated from the emission layer 220 on the third sub-pixel electrode 210B without wavelength conversion. The transmissive layer 530 may transmit blue light without conversion. For example, if (e.g., when) light with a wavelength of about 450 nm to about 495 nm is generated from the emission layer 220 on the third sub-pixel electrode 210B, the transmissive layer 530 may emit the light to the outside without wavelength conversion.

The transmissive layer 530 may include the third photosensitive polymer BR3 in which the third scattering particles SC3 are dispersed. In an embodiment, the transmissive layer 530 may not include quantum dots.

At least one selected from among first quantum dots 1152 and second quantum dots 1162 may include a semiconductor material, such as cadmium sulfide (CdS), cadmium telluride (CdTe), zinc sulfide (ZnS), and/or indium phosphide (InP). A quantum dot may have a size of several nanometers, and a wavelength of light after conversion may suitably vary according to the size of the quantum dot.

In an embodiment, a core of the quantum dot may be selected from a Group II-VI compound, a Group III-V compound, a Group IV-VI compound, a Group IV element, a Group IV compound, and a combination thereof.

The Group II-VI compound may be selected from the group consisting of: a binary compound selected from the group consisting of CdSe, CdTe, ZnS, ZnSe, ZnTe, ZnO, HgS, HgSe, HgTe, MgSe, MgS, and a mixture thereof; a ternary compound selected from the group consisting of AglnS, CulnS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof.

The Group III-V compound may be selected from the group consisting of: a binary compound selected from the group consisting of GaN, GaP, GaAs, GaSb, AlN, AlP, AlAs, AlSb, InN, InP, InAs, InSb, and a mixture thereof; a ternary compound selected from the group consisting of GaNP, GaNAs, GaNSb, GaPAs, GaPSb, AlNP, AlNAs, AlNSb, AlPAs, AlPSb, InGaP, InNP, InNAs, InNSb, InPAs, InPSb, GaAlNP, and a mixture thereof; and a quaternary compound selected from the group consisting of GaAlNAs, GaAlNSb, GaAlPAs, GaAlPSb, GalnNP, GalnNAs, GalnNSb, GalnPAs, GalnPSb, InAlNP, InAlNAs, InAlNSb, InAlPAs, InAlPSb, and a mixture thereof.

The Group IV-VI compound may be selected from the group consisting of: a binary compound selected from the group consisting of SnS, SnSe, SnTe, PbS, PbSe, PbTe, and a mixture thereof; a ternary compound selected from the group consisting of SnSeS, SnSeTe, SnSTe, PbSeS, PbSeTe, PbSTe, SnPbS, SnPbSe, SnPbTe, and a mixture thereof; and a quaternary compound selected from the group consisting of SnPbSSe, SnPbSeTe, SnPbSTe, and a mixture thereof. The Group IV element may be selected from the group consisting of Si, Ge, and a mixture thereof. The Group IV compound may be a binary compound selected from the group consisting of SiC, SiGe, and a mixture thereof.

In embodiments, the binary compound, the ternary compound, and/or the quaternary compound may be present in a particle at a uniform (e.g., substantially uniform) concentration, or the binary compound, the ternary compound, and the quaternary compound may have partially different concentration distributions and be present in the same particle. Also, the quantum dot may have a core/shell structure in which one quantum dot surrounds another quantum dot. An interface between the core and the shell may have a concentration gradient in which the concentration of elements present in the shell decreases along a direction toward the center of the quantum dot.

In some embodiments, the quantum dot may have a core-shell structure including a core and a shell surrounding the core. The shell of the quantum dot may act as a protective layer which prevents or reduces chemical denaturation of the core to maintain semiconductor characteristics, and/or as a charging layer which imparts electrophoretic characteristics to the quantum dot. The shell may be single-layered or multilayered. An interface between the core and the shell may have a concentration gradient in which the concentration of elements present in the shell decreases along a direction toward the center of the quantum dot. Examples of the shell of the quantum dot may be an oxide of a metal and/or non-metal, a semiconductor compound, or a combination thereof.

For example, the oxide of the metal and/or non-metal may include a binary compound, such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, and/or the like, and/or a ternary compound, such as MgAl₂O₄, CoFe₂O₄, NiFe₂O₄, CoMn₂O₄, and/or the like, but the disclosure is not limited thereto.

In embodiments, examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and/or the like, but the disclosure is not limited thereto.

In an embodiment, a full width at half maximum (FWHM) of an emission wavelength spectrum of the quantum dot may be about 45 nm or less, for example, about 40 nm or less, for example, about 30 nm or less, and within these ranges, the color purity and/or the color reproducibility may be improved. In embodiments, light emitted through the quantum dot is emitted in all (e.g., substantially all) directions, and thus, the wide viewing angle may be improved.

Also, the shape of the quantum dot is not particularly limited to the shape generally used in the related art, but in more detail, the quantum dot may be a spherical nanoparticle, a pyramidal nanoparticle, a multi-arm nanoparticle, a cubic nanoparticle, a nanotube, a nanowire, a nanofiber, and/or a nanoplate particle.

The quantum dot may adjust a color of light emitted according to a particle size, and accordingly, the quantum dot may have various suitable emission colors, such as blue, red, green, and/or the like.

The first scattering particles SC1, the second scattering particles SC2, and the third scattering particles SC3 may scatter light to allow more light to be emitted. The first scattering particles SC1, the second scattering particles SC2, and the third scattering particles SC3 may increase light extraction efficiency. At least one selected from among the first scattering particles SC1, the second scattering particles SC2, and the third scattering particles SC3 may include any suitable material among a metal and/or a metal oxide to evenly (e.g., substantially evenly) scatter light. For example, at least one selected from among the first scattering particles SC1, the second scattering particles SC2, and the third scattering particles SC3 may be at least one selected from among TiO₂, ZrO₂, Al₂O₃, In₂O₃, ZnO, SnO₂, Sb₂O₃, and ITO. In embodiments, at least one selected from among the first scattering particles SC1, the second scattering particles SC2, and the third scattering particles SC3 may have a refractive index of 1.5 or more. Therefore, the light extraction efficiency of the functional layer FNL may be improved. In some embodiments, at least one selected from among the first scattering particles SC1, the second scattering particles SC2, and the third scattering particles SC3 may be omitted.

The first photosensitive polymer BR1, the second photosensitive polymer BR2, and the third photosensitive polymer BR3 may be a light-transmissive organic material. For example, at least one selected from among the first photosensitive polymer BR1, the second photosensitive polymer BR2, and the third photosensitive polymer BR3 may include polymer resin, such as acryl, benzocyclobutene (BCB), and/or hexamethyldisiloxane (HMDSO).

The second thin-film encapsulation layer TFE2 may be on the second bank layer 600 and the functional layer FNL. The second thin-film encapsulation layer TFE2 may prevent, minimize, or reduce damage to or contamination of the functional layer FNL caused by penetration of impurities, such as moisture and/or air, from the outside, and may also prevent or reduce occurrence and propagation of cracks due to external forces. The second thin-film encapsulation layer TFE2 may improve reliability by strengthening protection of the functional layer FNL in the display apparatus 1 having a structure in which components are stacked on the single substrate 100 without including an upper substrate.

The second thin-film encapsulation layer TFE2 may cover the display region DA and may extend to the outside of the display region DA. The second thin-film encapsulation layer TFE2 may include at least one organic encapsulation layer and at least one inorganic encapsulation layer. For example, the second thin-film encapsulation layer TFE2 may include a third inorganic encapsulation layer 710, a second organic encapsulation layer 720, and a fourth inorganic encapsulation layer 730, which are sequentially stacked.

The third inorganic encapsulation layer 710 and the fourth inorganic encapsulation layer 730 may include at least one inorganic material selected from among aluminum oxide, titanium oxide, tantalum oxide, hafnium oxide, zinc oxide, silicon oxide, silicon nitride, and silicon oxynitride. The second organic encapsulation layer 720 may include a polymer-based material. The polymer-based material may include acrylic resin, epoxy-based resin, polyimide, and/or polyethylene. In an embodiment, the second organic encapsulation layer 720 may include acrylate. The second organic encapsulation layer 720 may be formed by curing a monomer and/or applying a polymer.

The color filter CFL may be above the second thin-film encapsulation layer TFE2. In an embodiment, the color filter CFL may be directly on a top surface (z-axis direction) of the second thin-film encapsulation layer TFE2, and may include the first color filter 810, the second color filter 820, and the third color filter 830. The first color filter 810 may be above the first quantum dot layer 510 to correspond to the first sub-pixel PX1, the second color filter 820 may be above the second quantum dot layer 520 to correspond to the second sub-pixel PX2, and the third color filter 830 may be above the transmissive layer 530 to correspond to the third sub-pixel PX3. The first to third color filters 810, 820, and 830 may include photosensitive resin. In embodiments, each of the first to third color filters 810, 820, and 830 may include a pigment and/or a dye, which exhibits its set or unique color.

The first color filter 810 may be a red color filter. For example, the first color filter 810 may only transmit light having a wavelength of about 630 nm to about 780 nm. The first color filter 810 may include a red pigment and/or dye. The second color filter 820 may be a green color filter. For example, the second color filter 820 may only transmit light having a wavelength of about 495 nm to about 570 nm. The second color filter 820 may include a green pigment and/or dye. The third color filter 830 may be a blue color filter. For example, the third color filter 830 may only transmit light having a wavelength of about 450 nm to about 495 nm. The third color filter 830 may include a blue pigment and/or dye.

The color filter CFL may reduce external light reflection of the display apparatus 1. For example, if (e.g., when) external light reaches the first color filter 810, only light of a preset wavelength as described above may pass through the first color filter 810, and light of other wavelengths may be absorbed or reflected by the first color filter 810. Therefore, only the light of the preset wavelength among the external light incident on the display apparatus 1 may pass through the first color filter 810, and a portion thereof may be reflected from the opposite electrode 230 and/or the first sub-pixel electrode 210R thereunder and may be emitted to the outside again. The first color filter 810 may reduce external light reflection by allowing, to be reflected to the outside, only a portion of external light incident on a region in which the first sub-pixel PX1 is provided. The same description applies to the second color filter 820 and the third color filter 830.

At least two selected from among the first color filter 810, the second color filter 820, and the third color filter 830 may overlap each other in the non-emission region. In this regard, FIG. 16 shows that respective portions of the first color filter 810, the second color filter 820, and the third color filter 830 may overlap each other in the non-emission region. The first color filter 810, the second color filter 820, and the third color filter 830 may at least partially overlap each other to define a light-blocking portion BP. Therefore, the color filter CFL may prevent or reduce color mixing even without an additional light-blocking member such as a black matrix.

In embodiments, a portion in which the first color filter 810 and the second color filter 820 overlap each other, a portion in which the second color filter 820 and the third color filter 830 overlap each other, and a portion in which the first color filter 810 and the third color filter 830 overlap each other may each act as a black matrix. For example, this is because, if (e.g., when) the first color filter 810 transmits only light having a wavelength of about 630 nm to about 780 nm and the third color filter 830 transmits only light having a wavelength of about 450 nm to about 495 nm, theoretically, there is no light that may pass through both the first color filter 810 and the third color filter 830, in the portion in which the first color filter 810 and the third color filter 830 overlap each other.

The light-blocking portion BP may overlap a partition wall between openings in the second bank layer 600, for example, a partition wall between the first opening COP1 and the second opening COP2, a partition wall between the second opening COP2 and the third opening COP3, or a partition wall between the first opening COP1 and the third opening COP3.

The overcoat layer 900 may cover the color filter CFL. The overcoat layer 900 may be an organic layer including an organic material. For example, the overcoat layer 900 may include a colorless, light-transmissive organic material, such as acrylic resin. The overcoat layer 900 may protect the color filter CFL and may flatten a top surface of the color filter CFL. A bottom surface of the overcoat layer 900 may have a concavo-convex structure due to a structure of a stack of the first to third color filters 810, 820, and 830 of the color filter CFL. A top surface of the overcoat layer 900 may be a flat surface. In some embodiments, another layer, such as a capping layer, may be further above the overcoat layer 900 and/or between the overcoat layer 900 and the color filter CFL. The capping layer may include an inorganic material. In some embodiments, the overcoat layer 900 may be covered with a window.

According to embodiments, ink droplets discharged into each of the printing regions may be uniformly (e.g., substantially uniformly) applied.

Accordingly, inkjet printing quality may be improved, and a display apparatus that prevents or reduces defects, such as mura, may be implemented.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various suitable changes in form and details may be made therein without departing from the spirit and scope as defined by the following claims, and equivalents thereof.

What is claimed is:

1. An inkjet printing method comprising:
generating volume data by measuring a volume of an ink droplet discharged from each of a plurality of nozzles;
generating particle number data by measuring a number of solute particles within the ink droplet discharged from each of the plurality of nozzles;
forming a first nozzle group by grouping, based on the volume data and the particle number data, nozzles that are to discharge ink into a first region from among the plurality of nozzles; and
discharging the ink into the first region by the nozzles of the first nozzle group.

2. The inkjet printing method of claim 1, wherein the forming of the first nozzle group comprises selecting some of the plurality of nozzles such that a number of solute particles within ink droplets discharged into the first region is close to a target number of particles.

3. The inkjet printing method of claim 2, wherein a sum of numbers of solute particles in respective ink droplets discharged by the nozzles of the first nozzle group is same as the target number of particles.

4. The inkjet printing method of claim 2, wherein the forming of the first nozzle group further comprises selecting some of the plurality of nozzles such that a volume of the ink droplets discharged into the first region is close to a target volume.

5. The inkjet printing method of claim 4, wherein a sum of volumes of respective ink droplets discharged by the nozzles of the first nozzle group is the same as the target volume.

6. The inkjet printing method of claim 4, wherein the forming of the first nozzle group further comprises selecting a combination of nozzles adjacent to the first region, from among combinations of nozzles, which satisfy the target number of particles and the target volume.

7. The inkjet printing method of claim 1, further comprising forming a second nozzle group by grouping, based on the volume data and the particle number data, nozzles that are to discharge ink to a second region from among the plurality of nozzles.

8. The inkjet printing method of claim 7, wherein the forming of the second nozzle group comprises selecting some of the plurality of nozzles such that a number of solute particles within ink droplets discharged into the second region is close to a target number of particles.

9. The inkjet printing method of claim 8, wherein the forming of the second nozzle group further comprises selecting some of the plurality of nozzles such that a volume of the ink droplets discharged into the second region is close to a target volume.

10. The inkjet printing method of claim 1, wherein the generating of the particle number data comprises measuring a number of particles within each of the ink droplets discharged from the nozzles by using laser induced breakdown spectroscopy.

11. The inkjet printing method of claim 1, wherein the generating of the volume data and the generating of the particle number data comprise information about a volume of a droplet according to a discharge waveform of each of the plurality of nozzles and information about a number of solute particles within the droplet.

12. The inkjet printing method of claim 1, wherein the generating of the volume data comprises adjusting the volume of the discharged ink droplet by adjusting a voltage applied to each of the plurality of nozzles.

13. An inkjet printing apparatus comprising:
a stage on which a display substrate is seated;
a spray unit that faces the stage and is configured to discharge ink onto the display substrate; and
a controller configured to control the spray unit,
wherein the spray unit comprises:
a head unit comprising a plurality of nozzles;
a volume measuring unit that is adjacent to the head unit and is configured to measure volumes of ink droplets discharged by the nozzles; and
a particle number measuring unit that is adjacent to the head unit and is configured to measure a number of solute particles within the ink droplets discharged by the nozzles.

14. The inkjet printing apparatus of claim 13, wherein the particle number measuring unit is further configured to measure a number of particles within each of the ink droplets discharged from the nozzles by using laser induced breakdown spectroscopy.

15. The inkjet printing apparatus of claim 13, wherein the volume measuring unit comprises at least one selected from among a line scan camera and a chromatic confocal sensor.

16. The inkjet printing apparatus of claim 13, wherein the controller is further configured to generate volume data by measuring a volume of an ink droplet discharged from each of the plurality of nozzles.

17. The inkjet printing apparatus of claim 16, wherein the controller is further configured to select, based on the volume data, some of the plurality of nozzles such that a volume of ink droplets discharged into a first region is close to a target volume.

18. The inkjet printing apparatus of claim 13, wherein the controller is further configured to generate particle number data by measuring a number of solute particles within an ink droplet discharged from each of the plurality of nozzles.

19. The inkjet printing apparatus of claim 18, wherein the controller is further configured to select, based on the particle number data, some of the plurality of nozzles such that a number of solute particles within ink droplets discharged into a first region is close to a target number of particles.

20. An electronic apparatus comprising:
a layer formed by an inkjet printing method comprising:
generating volume data by measuring a volume of an ink droplet discharged from each of a plurality of nozzles;
generating particle number data by measuring a number of solute particles within the ink droplet discharged from each of the plurality of nozzles;
forming a first nozzle group by grouping, based on the volume data and the particle number data, nozzles that are to discharge ink into a first region from among the plurality of nozzles; and
discharging the ink into the first region by the nozzles of the first nozzle group.
